(19) United States
(12) Patent Application Publication
(10) Pub. No.: US 2013/0194516 A1
(43) Pub. Date: Aug. 1, 2013

(54) TELEVISION AND ELECTRONIC APPARATUS

(71) Applicant: Kabushiki Kaisha Toshiba, Tokyo (JP)

(72) Inventors: Shinya Hayashiyama, Tachikawa-shi (JP); Minoru Takizawa, Sagamihara-shi (JP); Noboru Nishida, Ome-shi (JP); Makoto Tanaka, Ome-shi (JP)

(73) Assignee: KABUSHIKI KAISHA TOSHIBA, Tokyo (JP)

(21) Appl. No.: 13/693,710

(22) Filed: Dec. 4, 2012

(30) Foreign Application Priority Data
Jan. 31, 2012 (JP) 2012-019076

(51) Int. Cl. H05K 1/18; H04N 5/655

(52) U.S. Cl. CPC H05K 1/181; H04N 5/655
USPC 348/836; 361/752

(57) ABSTRACT

According to one embodiment, an electronic apparatus includes a housing, a circuit board in the housing, and a surface-mounted component. The circuit board includes a cutout. The surface-mounted component is along an edge of the cutout on the circuit board.

### CROSS-REFERENCE TO RELATED APPLICATIONS

This application is based upon and claims the benefit of priority from prior Japanese Patent Application No. 2012-019076, filed Jan. 31, 2012, the entire contents of which are incorporated herein by reference.

### FIELD

Embodiments described herein relate generally to electronic apparatuses including televisions.

### BACKGROUND

Some electronic apparatuses include reinforcing plates that are attached to circuit boards.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary perspective view of a television according to a first embodiment;

FIG. 2 is an exemplary cross-sectional view of the television illustrated in FIG. 1;

FIG. 3 is an exemplary rear view of the television illustrated in FIG. 1;

FIG. 4 is an exemplary perspective view of an electronic apparatus according to a second embodiment;

FIG. 5 is an exemplary perspective view of an inner surface of a cover illustrated in FIG. 4;

FIG. 6 is an exemplary perspective view of an inside of the electronic apparatus illustrated in FIG. 4;

FIG. 7 is an exemplary plan view of the inside of the electronic apparatus illustrated in FIG. 4;

FIG. 8 is an exemplary plan view of a circuit board illustrated in FIG. 7;

FIG. 9 is an exemplary cross-sectional view of the circuit board illustrated in FIG. 7;

FIG. 10 is an exemplary bottom view of a bottom surface of a second component illustrated in FIG. 8;

FIG. 11 is an exemplary enlarged plan view of a portion of the circuit board illustrated in FIG. 8;

FIG. 12 is an exemplary diagram illustrating an example of a method of manufacturing the circuit board illustrated in FIG. 8;

FIG. 13 is an exemplary plan view of a circuit board according to a modification of the second embodiment;

FIG. 14 is an exemplary cross-sectional view of the circuit board illustrated in FIG. 13;

FIG. 15 is an exemplary plan view of a circuit board according to a third embodiment;

FIG. 16 is an exemplary cross-sectional view of the circuit board illustrated in FIG. 15;

FIG. 17 is an exemplary plan view of a circuit board according to a fourth embodiment;

FIG. 18 is an exemplary plan view of a circuit board according to a fifth embodiment;

FIG. 19 is an exemplary perspective view of a circuit board according to a sixth embodiment;

FIG. 20 is an exemplary perspective view of the circuit board illustrated in FIG. 19;

FIG. 21 is an exemplary perspective view of a circuit board according to a modification of the sixth embodiment;

FIG. 22 is an exemplary perspective view of a circuit board according to another modification of the sixth embodiment;

FIG. 23 is an exemplary cross-sectional view of the circuit board illustrated in FIG. 22;

FIG. 24 is an exemplary plan view of a circuit board according to another modification of the sixth embodiment;

FIG. 25 is an exemplary cross-sectional view of the circuit board illustrated in FIG. 24;

FIG. 26 is an exemplary perspective view of a circuit board according to a seventh embodiment;

FIG. 27 is an exemplary plan view of a circuit board according to an eighth embodiment;

FIG. 28 is an exemplary cross-sectional view of a circuit board according to a ninth embodiment;

FIG. 29 is an exemplary plan view of the circuit board illustrated in FIG. 28;

FIG. 30 is an exemplary cross-sectional view of the circuit board illustrated in FIG. 28;

FIG. 31 is an exemplary diagram illustrating an operation of the circuit board illustrated in FIG. 28;

FIG. 32 is an exemplary cross-sectional view of a circuit board according to a first modification of the ninth embodiment;

FIG. 33 is an exemplary cross-sectional view of a circuit board according to a second modification of the ninth embodiment;

FIG. 34 is an exemplary cross-sectional view of a circuit board according to a third modification of the ninth embodiment;

FIG. 35 is an exemplary plan view of a circuit board according to a tenth embodiment;

FIG. 36 is an exemplary plan view of a circuit board according to a modification of the tenth embodiment;

FIG. 37 is an exemplary cross-sectional view of a circuit board according to an eleventh embodiment;

FIG. 38 is an exemplary cross-sectional view of a circuit board according to a twelfth embodiment;

FIG. 39 is an exemplary perspective view of a circuit board according to a thirteenth embodiment;

FIG. 40 is an exemplary plan view of the circuit board illustrated in FIG. 39;

FIG. 41 is an exemplary plan view of a circuit board according to a first modification of the thirteenth embodiment;

FIG. 42 is an exemplary plan view of a circuit board according to a second modification of the thirteenth embodiment;

FIG. 43 is an exemplary plan view of a circuit board according to a third modification of the thirteenth embodiment;

FIG. 44 is an exemplary plan view of a first modification of a reinforcing component;

FIG. 45 is an exemplary plan view of a second modification of the reinforcing component;

FIG. 46 is an exemplary plan view of a third modification of the reinforcing component;

FIG. 47 is an exemplary plan view of a fourth modification of the reinforcing component;

FIG. 48 is an exemplary plan view of a fifth modification of the reinforcing component; and

FIG. 49 is an exemplary plan view of a sixth modification of the reinforcing component.

### DETAILED DESCRIPTION

Various embodiments will be described hereinafter with reference to the accompanying drawings.

In general, according to one embodiment, an electronic apparatus comprises a housing, a circuit board in the housing, and a surface-mounted component. The circuit board comprises a cutout. The surface-mounted component is along an edge of the cutout on the circuit board.

Hereinafter, embodiments will be described with reference to the drawings.

### First Embodiment

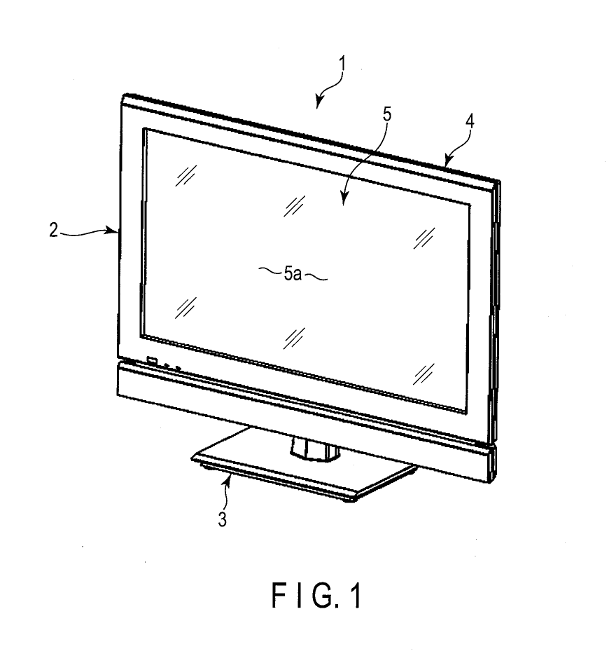

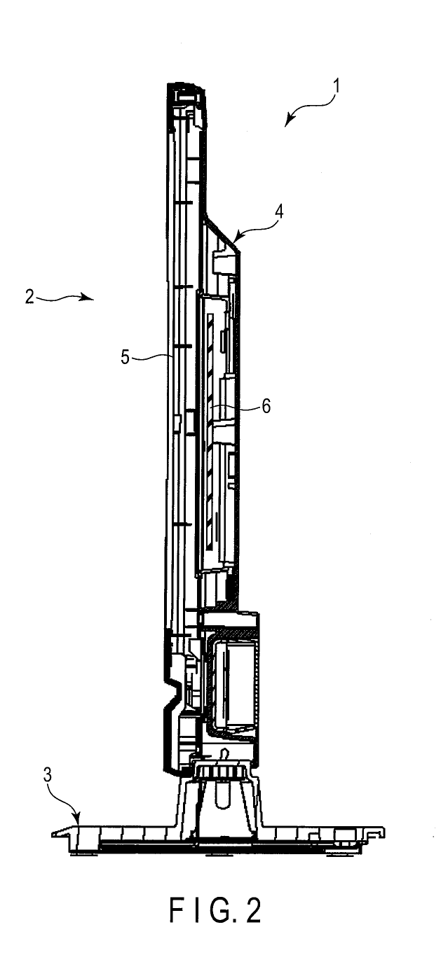

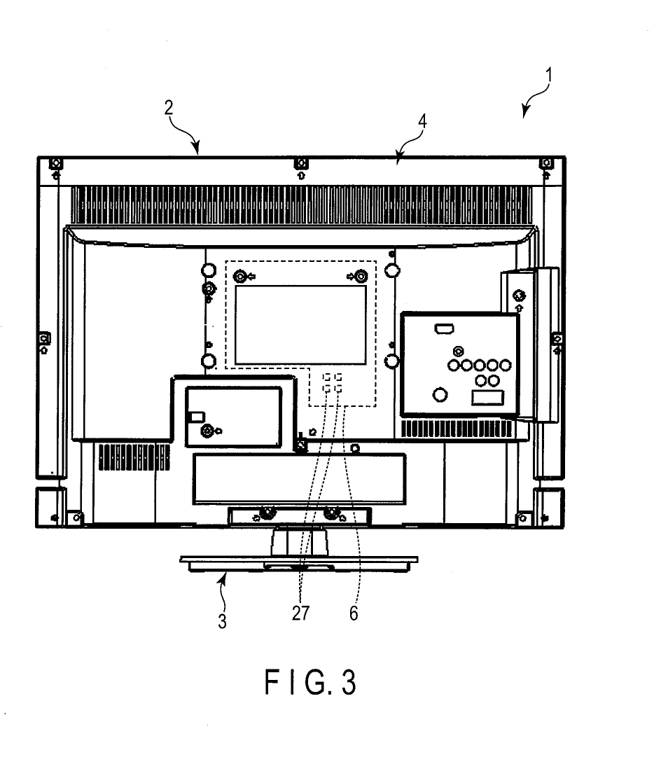

FIGS. 1 to 3 illustrate a television 1 according to a first embodiment. The television 1 is an example of an “electronic apparatus”. The television 1 includes a display unit 2 and a stand 3 supporting the display unit 2. The display unit 2 includes a housing 4. The housing 4 includes a display 5 and a circuit board 6. The circuit board 6 is electrically connected to the display 5. The circuit board 6 includes reinforcing portions 27.

These components have substantially the same structures as those in a second embodiment. Therefore, the second embodiment will be described in detail. Components having the same or similar functions as those in the second embodiment are denoted by the same reference numerals and the description thereof will not be repeated.

### Second Embodiment

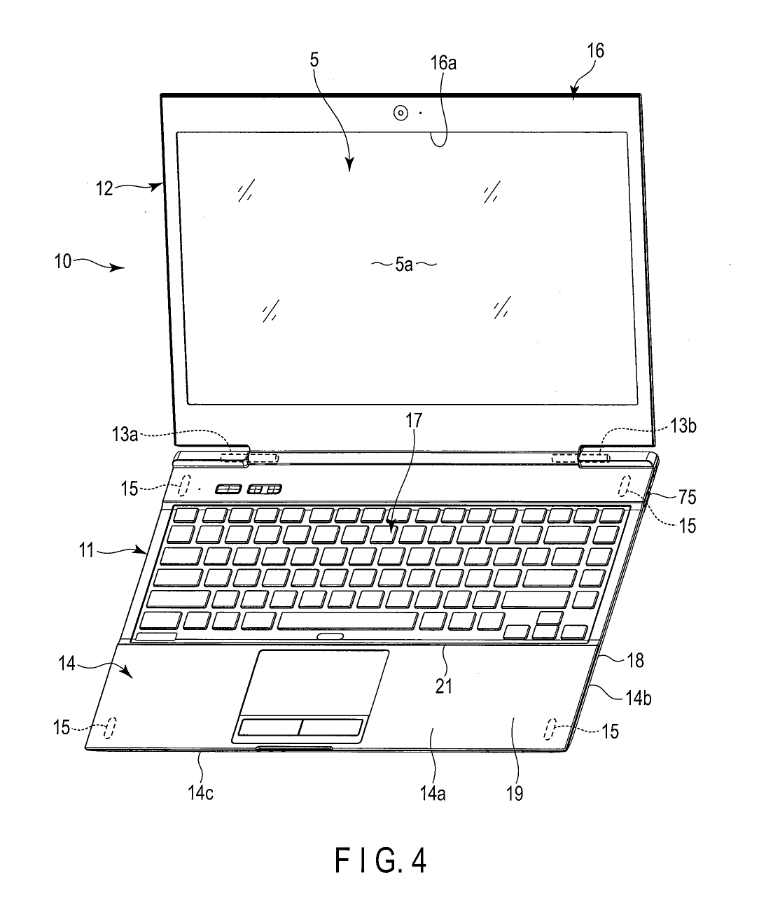

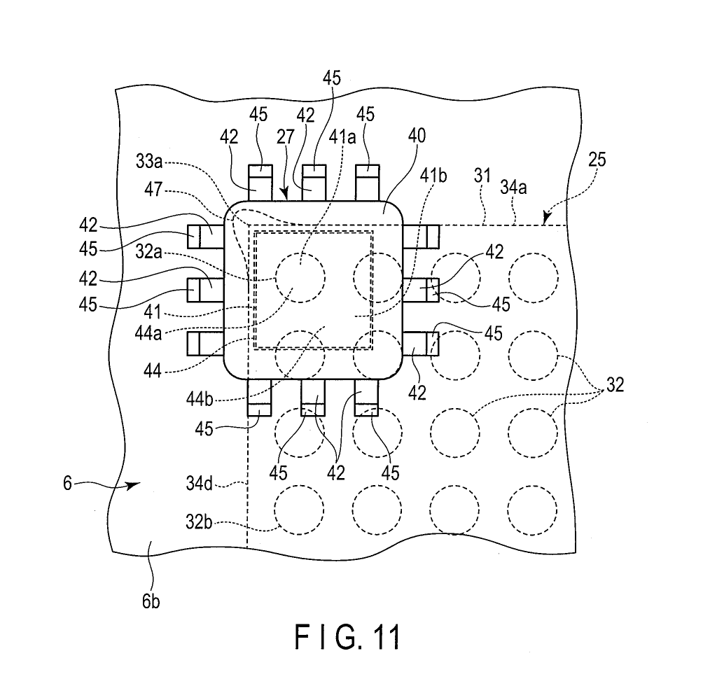

Next, an electronic apparatus 10 according to a second embodiment will be described with reference to FIGS. 4 to 12. The electronic apparatus 10 is, for example, a notebook portable computer (notebook PC). Electronic apparatuses to which this embodiment and the third to thirteenth embodiments, which will be described below, can be applied are not limited to the notebook PC. All of the embodiments and modifications in the specification can be widely applied to various electronic apparatuses including slate portable computers (i.e., slate PCs or tablet PCs), televisions, mobile phones (including smart phones), and game machines.

As illustrated in FIG. 4, the electronic apparatus 10 includes a first unit 11, a second unit 12, and hinges 13a and 13b. The first unit 11 is, for example, a main unit provided with a main board. The first unit 11 includes a first housing 14. The first housing 14 includes, for example, a circuit board 6 serving as a main board. The first housing 14 includes an upper wall 14a, a lower wall 14b, and a circumferential wall 14c and has a flat box shape.

The lower wall 14b faces a desk surface (i.e., mounting surface, outer surface, or outer mounting surface) when the electronic apparatus 10 is placed on a desk. The lower wall 14b includes, for example, a plurality of leg portions 15 (i.e., supporting portions) which come into contact with the desk surface. The upper wall 14a is opposite to the lower wall 14b. A gap is formed between the upper wall 14a and the lower wall 14b and the upper wall 14a extends substantially in parallel to the lower wall 14b. The circumferential wall 14c connects the edge of the lower wall 14b and the edge of the upper wall 14a.

As illustrated in FIG. 4, the second unit 12 is, for example, a display unit and includes a second housing 16 and a display 5 in the second housing 16. The display 5 is, for example, a liquid crystal display, but is not limited thereto. The display 5 includes a display screen 5a. The second housing 16 includes an opening 16a through which the display screen 5a is exposed.

The second housing 16 is rotatably (i.e., openably) connected to the end of the first housing 14 by the hinges 13a and 13b. In this way, the second housing 16 can be rotated between a first position where the first housing 14 and the second housing 16 overlap each other and a second position where the first housing 14 and the second housing 16 are opened.

Next, the mounting structure of the electronic apparatus 10 will be described.

As illustrated in FIG. 4, a keyboard 17 is provided on the upper wall 14a of the first housing 14 (hereinafter, referred to as the housing 14). The keyboard 17 is an example of an “input unit (i.e., input receiving unit)”. However, the input unit is not limited thereto. For example, the input unit may be a touch panel (i.e., touch sensor) or other input devices.

The housing 14 includes a base 18 (e.g., lower cover) and a cover 19 (e.g., upper cover). The base 18 includes the lower wall 14b and a portion of the circumferential wall 14c. The cover 19 includes the upper wall 14a and a portion of the circumferential wall 14c. In this embodiment, the base 18 and the cover 19 are combined to form the housing 14.

The cover 19 includes a keyboard attachment portion 21 (i.e., an attachment portion or an input unit attachment portion) to which the keyboard 17 is attached. The keyboard attachment portion 21 extends over the substantially overall width of the housing 14 in the longitudinal direction of the housing 14. The keyboard attachment portion 21 is recessed from the upper wall 14a. In this way, the height of the keyboard 17 attached to the keyboard attachment portion 21 is substantially equal to or slightly higher than that of the upper wall 14a.

FIG. 5 illustrates the inner surface of the cover 19 which is turned inside out. The keyboard attachment portion 21 has a honeycomb structure. That is, the keyboard attachment portion 21 includes a plurality of openings 21a and a plurality of beams 21b (i.e., supporting portions) which extend between the openings 21a. The plurality of beams 21b are connected to each other to form a hexagonal or rectangular frame. The beams 21b are provided in the entire region of the keyboard attachment portion 21 and support the keyboard 17 from the lower side.

The honeycomb structure can ensure the strength (i.e., rigidity) of the keyboard attachment portion 21 and reduce the weight thereof. In this way, even when the user strongly strikes the keyboard 17, the keyboard attachment portion 21 is less likely to be bent.

As illustrated in FIG. 5, a circuit board 6, a battery 23, and speakers 24a and 24a are attached to the inner surface of the cover 19. The circuit board 6 is attached to the inner surface (e.g., lower surface) of the keyboard attachment portion 21 and is disposed below the keyboard attachment portion 21. The circuit board 6 is electrically connected to the display 5 through, for example, a cable.

The circuit board 6 includes a first surface 6a and a second surface 6b. The second surface 6b is opposite to the first surface 6a. In this embodiment, the first surface 6a is a lower surface. The second surface 6b is an upper surface. The first surface 6a and the second surface 6b may be reversed.

In this embodiment, tall components (i.e., components with a large height) are concentrated on the first surface 6a. On the other hand, short components (i.e., components with a small height) are mounted on the second surface 6b. In this way, the second surface 6b can be arranged close to the keyboard attachment portion 21. This contributes to reducing the thickness of the electronic apparatus 10.

As illustrated in FIG. 5, for example, two first components 25 and 26 are mounted on the first surface 6a of the circuit board 6. Each of the first components 25 and 26 is an example of a “component”, a “first surface-mounted component”, a “heating element”, a “heat-generating component”, or an “electronic component”. The first components 25 and 26 are, for example, surface-mounting-type semiconductor components. The first components 25 and 26 are supplied with power and generate heat.

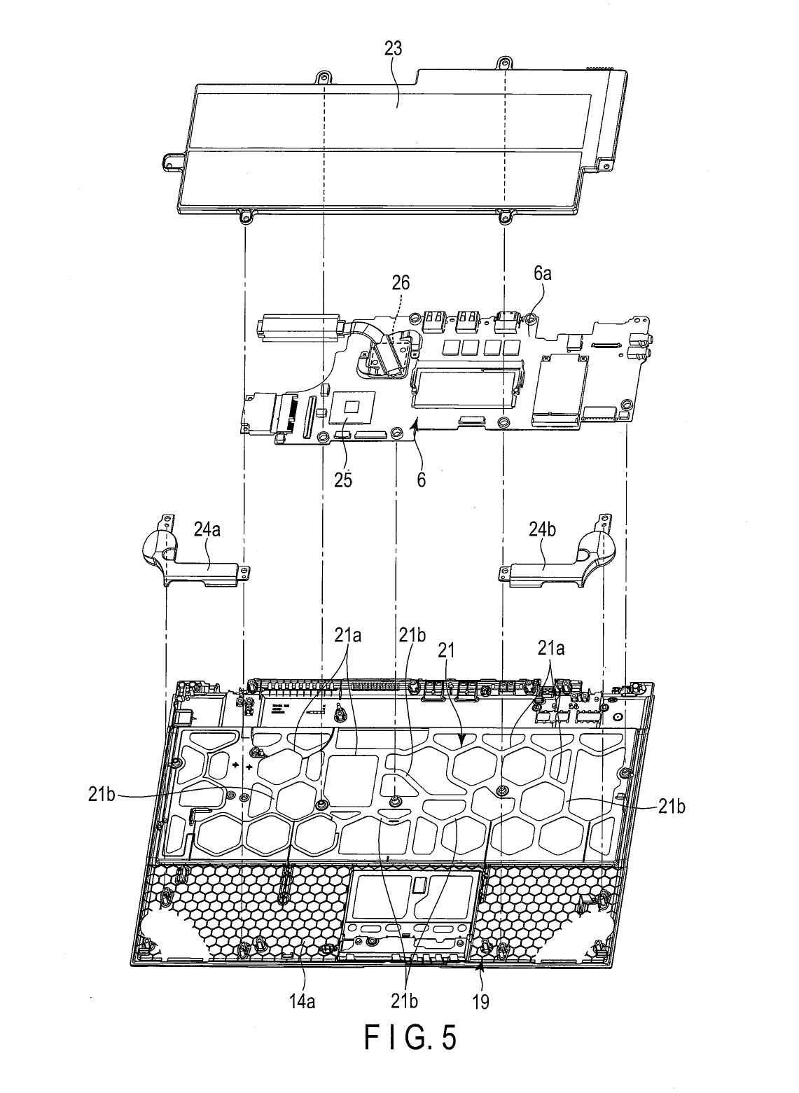

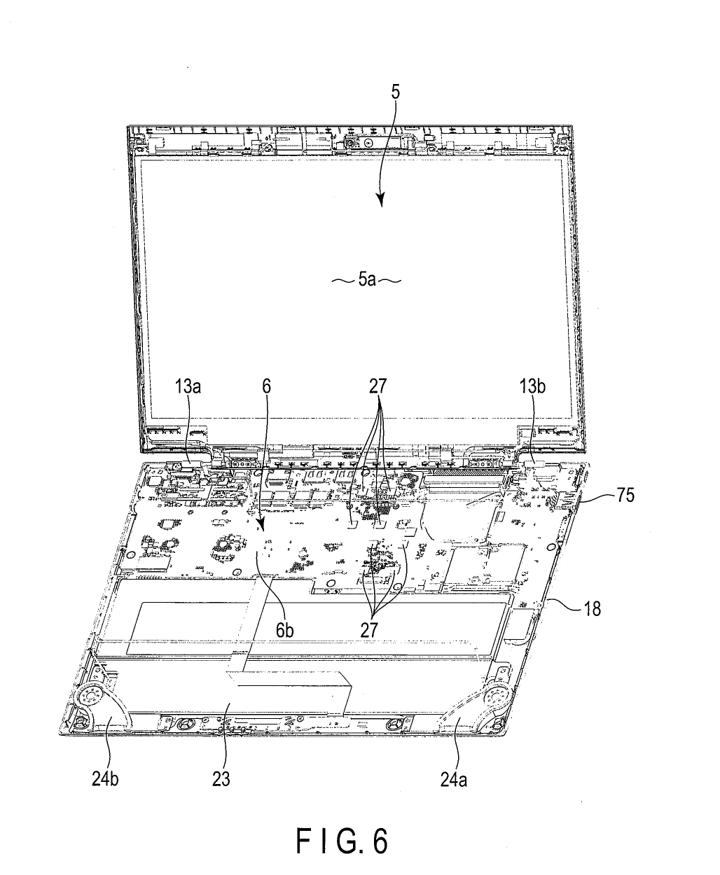

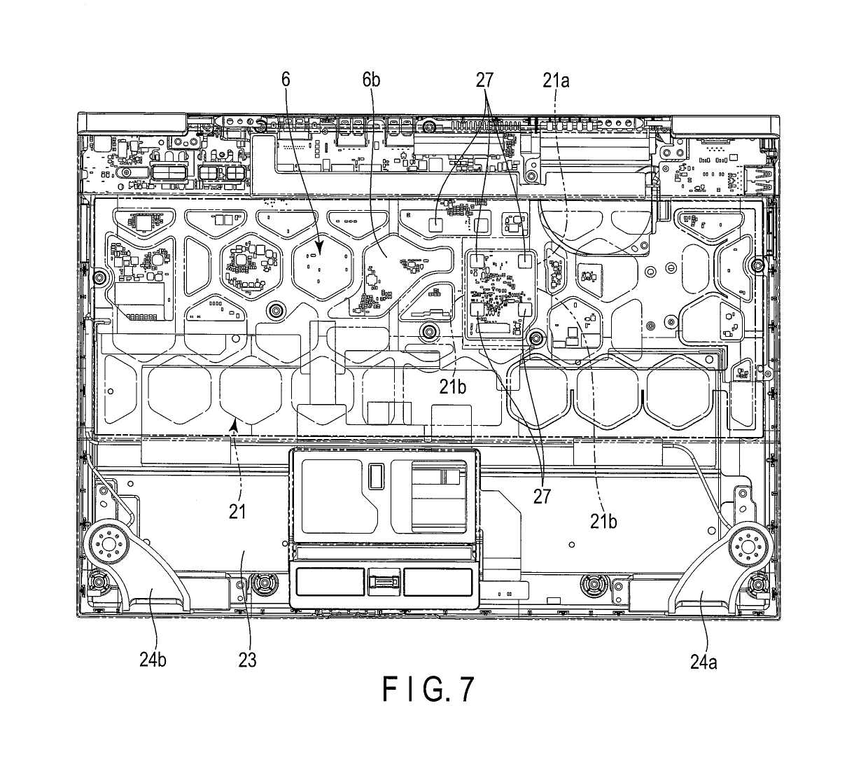

As illustrated in FIGS. 6 and 7, a plurality of second components 27 are mounted on the second surface 6b of the circuit board 6. The second component 27 is an example of a “reinforcing component”, a “reinforcing portion”, a “component”, a “second surface-mounted component”, or an “electronic component”. The second components 27 are disposed on the back side of the first components 25 and 26. Next, the relation between the first component 25 and the second components 27 will be described in detail. The relation between the first component 26 and the second components 27 is substantially the same as the relation between the first component 25 and the second components 27. The plurality of second components 27 may be the same type of components or they have different functions or shapes.

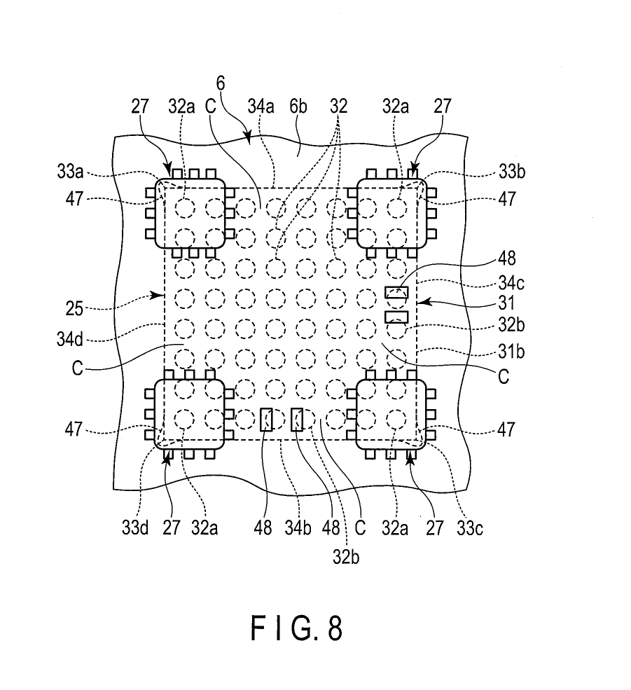

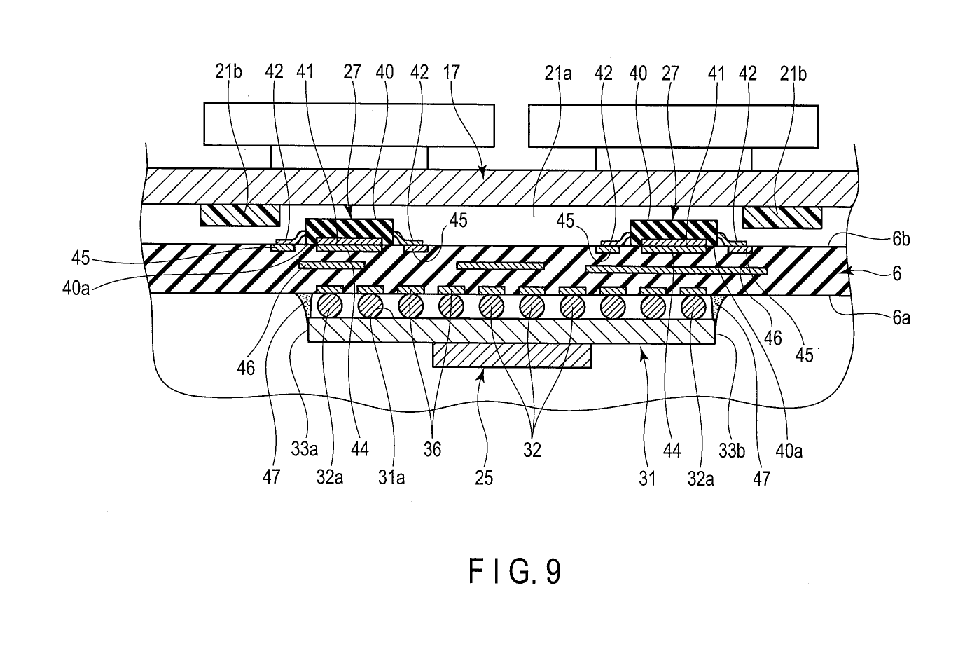

As illustrated in FIGS. 8 and 9, an example of the first component 25 is a ball grid array (BGA). The first component 25 is not limited to BGA, but may be various components including area array-type components or other semiconductor components.

The first component 25 includes a package 31 and a plurality of bumps 32. The package 31 includes a board and a semiconductor (i.e., electronic component) on the board and is an example of a “semiconductor portion”, a “semiconductor mounting portion”, a “component mounting portion”, a “chip portion”, a “chip mounting portion”, a “board portion”, a “main portion”, or an “outline portion”.

The package 31 is a case which protects a semiconductor or an electronic component from an external environment and is an example of a sealing portion. In this embodiment, the package 31 covers the entire semiconductor or electronic component, but the embodiments are not limited thereto. A portion of the semiconductor or electronic component may be exposed to the outside.

As illustrated in FIG. 8, the package 31 has, for example, a rectangular flat box shape and includes four corners 33a, 33b, 33c, and 33d and four sides 34a, 34b, 34c, and 34d. The first corner 33a is near the second corner 33b and the fourth corner 33d and is diagonally opposite to the third corner 33c. Similarly, the second corner 33b is near the first corner 33a and the third corner 33c and is diagonally opposite to the fourth corner 33d. Each of the four corners 33a, 33b, 33c, and 33d may be rounded.

The first side 34a (i.e., a first edge, a first end, or a first straight portion) extends between the first corner 33a and the second corner 33b. The second side 34b (i.e., a second edge, a second end, or a second straight portion) is opposite to the first side 34a and extends between the third corner 33c and the fourth corner 33d. The third side 34c (i.e., a third edge, a third end, or a third straight portion) extends between the second corner 33b and the third corner 33c. The fourth side 34d (i.e., a fourth edge, a fourth end, or a fourth straight portion) is opposite to the third side 34c and extends between the first corner 33a and the fourth corner 33d.

As illustrated in FIG. 9, the package 31 includes a bottom surface 31a (i.e., a surface facing the circuit board 6). The plurality of bumps 32 are provided on the bottom surface 31a of the package 31. The bump 32 is an example of an “attaching portion”, a “fixing portion”, a “bonding portion”, a “connection portion”, “solder portion”, or a “soldering portion”.

As illustrated in FIG. 8, the plurality of bumps 32 are disposed inside the outer circumferential surface (i.e., side surface) 31b of the package 31 (i.e., inside the four sides 34a, 34b, 34c, and 34d). The plurality of bumps 32 are arranged in a lattice shape along the four sides 34a, 34b, 34c, and 34d.

As illustrated in FIG. 9, pads 36 (i.e., conductive portions, connection portions, fixing portions, or metal portions) corresponding to the bumps 32 are provided on the first surface 6a of the circuit board 6. The bumps 32 are soldered to the pad 36 and are electrically connected to the first surface 6a of the circuit board 6. In this way, the first component 25 is surface-mounted on the first surface 6a of the circuit board 6.

As illustrated in FIG. 8, the plurality of bumps 32 include first bumps 32a and second bumps 32b. An example of the first bump 32a is a corner bump and the first bump 32a is closest to any one of the four corners 33a, 33b, 33c, and 33d. In other words, the first bumps 32a are disposed at the corners 33a, 33b, 33c, and 33d. That is, the first component 25 includes four first bumps 32a. The four first bumps 32a are separately disposed at the four corners 33a, 33b, 33c, and 33d.

The first bumps 32a are furthest away from the center of the first component 25. The first bumps 32a are disposed at the corners among the plurality of bumps 32 which are arranged in a lattice shape. The first bumps 32a are disposed at the end (i.e., edge) of the package 31.

The second bumps 32b are disposed closer to the center of any one of the four sides 34a, 34b, 34c, and 34d than the first bumps 32a. In other words, the second bumps 32b are further away from the corners 33a, 33b, 33c, and 34d than the first bumps 32a. For example, some second bumps 32b are disposed on the outermost circumference of a plurality of bumps 32 and are arranged along the sides 34a, 34b, 34c, and 34d. The arrangement of the second bumps 32b is not limited thereto, but may be disposed at the center of the first component 25.

As illustrated in FIG. 8, four second components 27 corresponding to the first components 25 are provided on the second surface 6b of the circuit board 6. The size of the second component 27 is less than that of the first component 25. A signal may flow between at least one of the second components 27 and the circuit board 6 such that the second component 27 has an electrical function, or no signal may flow between at least one of the second components 27 and the circuit board 6 such that the second component 27 does not have an electrical function (i.e., the second component 27 is a dummy component). The four second components 27 are separately provided on the bottom sides of the four corners 33a, 33b, 33c, and 33d of the first component 25.

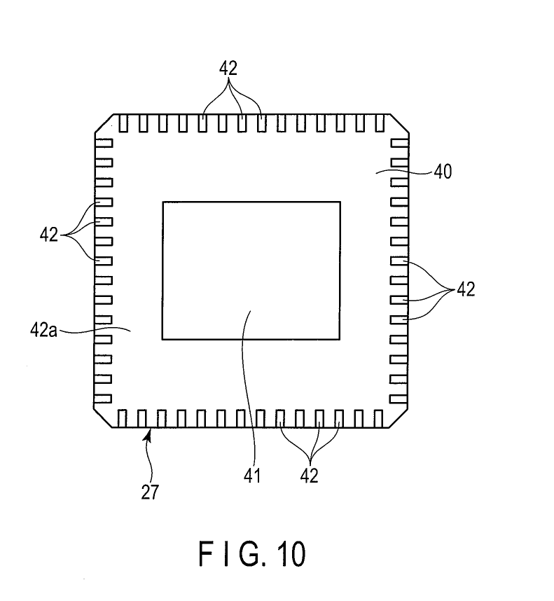

As illustrated in FIGS. 9 and 10, an example of the second component 27 is QFN and includes a resin portion 40, a first electrode 41, and second electrodes 42. The resin portion 40 (i.e., sealing portion) corresponds to the above-mentioned “package” and includes a board and a semiconductor (i.e., electronic component) on the board. The resin portion 40 includes a bottom surface 40a (i.e., a surface facing the circuit board 6).

The first electrode 41 (i.e., a first fixing portion, a first bonding portion, or a first connection portion) is a bottom electrode which is provided on the bottom surface 40a of the resin portion 40 and has an area more than that of the second electrode 42. The first electrode 41 is a heat dissipating pad. The first electrode 41 is, for example, a ground or power electrode pad. The plurality of second electrodes 42 (i.e., second fixing portions, second bonding portions, or second connection portions) are provided at the end (i.e., edge) of the resin portion 40. The second electrode 42 is, for example, a signal terminal.

As illustrated in FIGS. 9 to 11, pads 44 and 45 (i.e., conductive portions, connection portions, fixing portions, or metal portions) are provided on the second surface 6b of the circuit board 6. The first pad 44 corresponds to the first electrode 41 of the second component 27 and has an area more than that of the second pad 45. The first pad 44 is disposed on the back side of the first component 25. In this embodiment, the first pad 44 is an example of a “first pad region”. The first pad 44 includes, for example, a first portion 44a (i.e., first region) that is disposed on the back side of the first bump 32a and a second portion 44b (i.e., second region) that is disposed closer to the center of the first component 25 than the first portion 44a.

The second pad 45 corresponds to the second electrode 42 of the second component 27 and is provided around the first pad 44. At least one second pad 45 has a portion (i.e., region) which is disposed outside the first bump 32a with respect to the center of the first component 25. In this embodiment, the second pad 45 is an example of a “second pad region”. In the specification, a side which is away from the center of the first component 25 is defined as the “outside” and a side which is close to the center of the first component 25 is defined as the “inside”. In other words, the “outside” is opposite to the center of the first component 25. The “inside” is close to the center of the first component 25.

As illustrated in FIGS. 9 to 11, the first electrode 41 of the second component 27 is soldered to the first pad 44. The second electrode 42 of the second component 27 is soldered to the second pad 45. In this way, the second component 27 is mounted on the second surface 6b of the circuit board 6 on the back side of the first bump 32a (i.e., the back side of the first corner 33a).

Specifically, the first electrode 41 is fixed to the second surface 6b of the circuit board 6 on the back side of the first component 25. The first electrode 41 includes a first portion 41a and a second portion 41b. The first portion 41a is disposed on the back side of the first bump 32a and is fixed to the first portion 44a of the first pad 44. The second portion 41b is disposed closer to the center of the first component 25 than the first portion 41a and is fixed to the second portion 44b of the first pad 44. At least one second electrode 42 is fixed to the second pad 45 outside the first bump 32a with respect to the center of the first component 25.

As illustrated in FIG. 9, the circuit board 6 includes a wiring pattern 46 (e.g., an inner layer pattern, a signal pattern, or a conductor pattern). The wiring pattern 46 is provided on the inner layer of the circuit board 6. The wiring pattern 46 is disposed between the second component 27 and the first surface 6a of the circuit board 6. That is, a portion of the wiring pattern 46 is disposed between the second component 27 and the first bump 32a.

As illustrated in FIGS. 8, 9, and 11, adhesives 47 (i.e., adhesive portion, fixing portion) formed by an adhesive are provided at the corners 33a, 33b, 33c, and 33d of the first component 25. The adhesives 47 are provided on the outer circumferential surfaces of the corners 33a, 33b, 33c, and 33d and fix the corners 33a, 33b, 33c, and 33d and the circuit board 6. The adhesive 47 is disposed outside the first bump 32a with respect to the center of the first component 25. The adhesive 47 is an example of a protective portion that protects the corners 33a, 33b, 33c, and 33d (i.e., first bumps 32a).

In this embodiment, at least one second pad 45 is disposed outside the adhesive 47 with respect to the center of the first component 25. That is, a portion of the second pad 45 is disposed outside the adhesive 47. At least one second electrode 42 is fixed to the second pad 45 outside the adhesive 47 with respect to the center of the first component 25.

As illustrated in FIG. 8, a gap C is provided between a plurality of second components 27. The gap C is disposed on the back side of the second bump 32b. That is, the circuit board 6 includes a region (i.e., non-reinforcing region) in which the pads 44 and 45 and the second component 27 are not provided. The size of the gap C is larger than, for example, that of the second component 27.

An electronic component 48 (i.e., a third component or a third surface-mounted component) is mounted on the second surface 6b of the circuit board 6. The electronic component 48 is electrically connected to the circuit board 6 and a signal flows between the electronic component 48 and the circuit board 6. That is, the electronic component 48 has an electrical function. The electronic component 48 is disposed on the back side of the first component 25. The electronic component 48 is disposed between a plurality of second components 27 (i.e., in the gap C).

As illustrated in FIGS. 7 to 9, the second component 27 on the second surface 6b faces the opening 21a of the keyboard attachment portion 21. The end (e.g., the leading end or the upper end) of the second component 27 is inserted into, for example, the opening 21a and is disposed between the beams 21b.

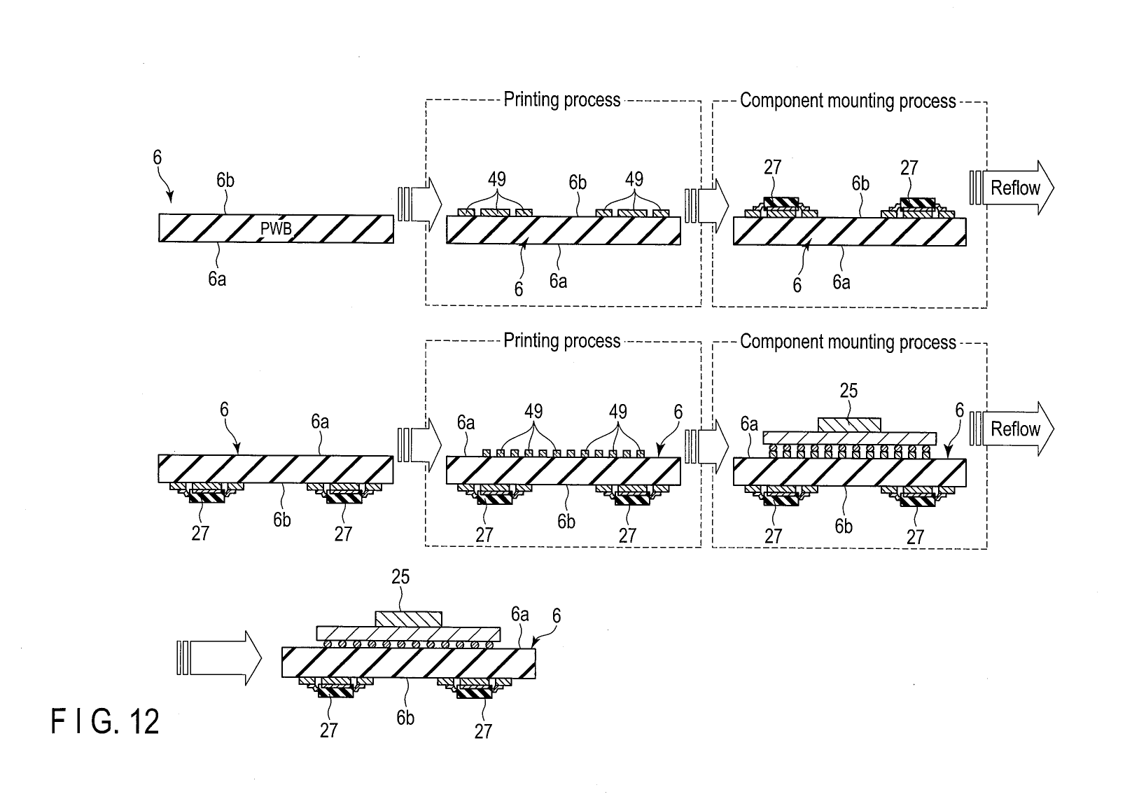

Next, an example of the mounting process of the second component 27 will be described with reference to FIG. 12. As illustrated in FIG. 12, first, the circuit board 6 is prepared. Then, in a first printing process, solder 49 (e.g., solder paste) is printed on the second surface 6b of the circuit board 6. Then, in a first component mounting process, the second components 27 are mounted. The second components 27 are fixed to the second surface 6b by a first reflow process. That is, the second components 27 are mounted on the circuit board 6 by a surface mounting process together with other components (e.g., the electronic components 48) on the second surface 6b.

Then, in a second printing process, the solder 49 is printed on the first surface 6a of the circuit board 6. Then, in a second component mounting process, the first component 25 is mounted. The first component 25 is fixed to the first surface 6a by a second reflow process. In this way, the circuit board 6 is completed.

According to this structure, it is possible to improve the impact resistance of the electronic apparatus 10.

When a reinforcing plate (e.g., back plate) is provided on the back side of the component of the circuit board, in general, the reinforcing plate has a size which is larger than that of the component and is sufficient to cover the entire component. In this way, the rigidity of the circuit board is improved and the component is protected.

However, the inventors found that improvement in the rigidity of the circuit board did not necessarily lead to the protection of the component. Specifically, the inventors tested the lifespan of two boards on which the same component was mounted. The two boards are a first board and a second board which is thicker (i.e., more rigid) than the first board. An impact was repeatedly applied to the two boards (e.g.', a drop test) and the number of times an impact was applied until a defect occurred in the circuit board was counted.

In general, it is considered until now that the higher the rigidity of the second board is, the longer the lifespan of the circuit board (i.e., the lifespan of a component) is. However, the test proved that the lifespan of the second board was shorter than that of the first board.

The inventors analyze the reason as follows. That is, when an impact is applied to the circuit board, stress which oscillates with a predetermined amplitude is repeatedly applied as vibration to the circuit board. In the case of the circuit board with low rigidity, the peak of stress is high, but the number of times stress is repeatedly applied tends to be reduced.

On the other hand, in the case of the circuit board with high rigidity, the peak of stress is low, but the number of times stress is repeatedly applied tends to increase. Therefore, the number of times stress is repeatedly applied when an impact is applied is one of the important factors of the lifespan. In the circuit board with high rigidity, it is considered that stress is likely to be applied and the lifespan is reduced.

The above proves that the attachment of the reinforcing plate covering the entire component is effective for a static load, is not effective for a dynamic load, such as vibration or impact, and is likely to reduce the lifespan of the circuit board. Therefore, in this embodiment, a reinforcing portion (i.e., second component 27) is provided which minimizes the rigidity of the circuit board and locally reinforces a portion of the circuit board which is likely to be damaged.

That is, in this embodiment, the electronic apparatus 10 includes the first component 25 comprising an attaching portion (e.g., the first bump 32a) which is fixed to the first surface 6a of the circuit board 6 and the second component 27 which is mounted on the second surface 6b of the circuit board 6 and is disposed on the back side of the attaching portion of the first component 25. According to this structure, the second component 27 can locally reinforce the back side of the fixing portion of the first component 25. In this way, it is possible to improve the resistance of the circuit board 6 to a dynamic load and thus improve the impact resistance of the electronic apparatus 10.

In this embodiment, the first component 25 includes the package 31 having the corner 33a and the plurality of bumps 32 which are provided on the bottom surface 31a of the package 31. In the first component 25, when an impact is applied to the electronic apparatus 10, stress is likely to be concentrated on the first bump 32a closest to the corner 33a among the plurality of bumps 32 and the first bump 32a is likely to be damaged.

In this embodiment, the first pad 44 which is disposed on the back side of the first component 25 and the second pad 45 having a portion which is disposed outside the first bump 32a are provided on the second surface 6b of the circuit board 6. The second component 27 is fixed to the first pad 44 and the second pad 45. According to this structure, a stress wave transmitted from the end of the circuit board 6 to the first component 25 is transmitted to the second component 27 prior to the first bump 32a. In this way, a portion of the impact can be escaped (i.e., dispersed) to the second component 27.

In other words, the second component 27 can receive the stress wave transmitted from the end of the circuit board 6 to the first component 25 outside the first bump 32a. In this way, it is possible to shift a stress concentration point to the outside of the first bump 32a. Therefore, it is possible to reduce the load of the first bump 32a on which stress is likely to be concentrated and thus improve impact resistance. In addition, when the size of the second component 27 is smaller than that of the first component 25, it is possible to protect the first bump 32a without excessively increasing the rigidity of the circuit board 6.

In this embodiment, the second component 27 is an electronic component including the resin portion 40 and the electrodes 41 and 42 which are attached to the resin portion 40. That is, in this embodiment, the existing general-purpose electronic component is mounted on the back side of the first bump 32a to protect the first bump 32a, without newly designing a special reinforcing component. According to this structure, it is possible to reduce development costs, as compared to a case in which a special reinforcing component is newly designed. In addition, since a special manufacturing jig is not needed, it is possible to reduce manufacturing costs.

In this embodiment, the second component 27 is fixed to the circuit board 6 by solder. According to this structure, a hole, such as a screw hole, is not needed and it is possible to ensure a large wiring space on the inner layer of the circuit board 6. When a reinforcing component can be mounted together with other components by the surface mounting process, a screwing process or a jig for a back plate, is not needed. In addition, a post-process, such as adhesion, taping, or screwing, is not needed. This contributes to reducing manufacturing costs.

In this embodiment, the gap C is provided between a plurality of second components 27. According to this structure, it is possible to improve the impact resistance of the circuit board 6 without increasing the rigidity of the circuit board 6.

In this embodiment, the electronic apparatus 10 includes the electronic component 48 disposed between a plurality of second components 27. According to this structure, the gap C between a plurality of second components 27 is used as a mounting region and it is possible to achieve high-density mounting.

In this embodiment, the second component 27 includes the first electrode 41 which is, for example, a heat dissipating pad and has a relatively large area. According to the second component 27, the bonding strength between the second component 27 and the circuit board 6 is high and it is possible to protect the first bump 32a at a high level. In this embodiment, the first electrode 41 is disposed on the back side of the first bump 32a. According to this structure, it is possible to protect the first bump 32a with a high level.

In this embodiment, the electronic apparatus 10 includes the adhesive 47 which is provided outside the first bump 32a. When the adhesive 47 is provided, a portion of the impact transmitted from the end of the circuit board 6 is escaped (i.e., dispersed) to the adhesive 47 outside the first bump 32a and it is possible to protect the first bump 32a.

In this embodiment, at least a portion of the second pad 45 is disposed outside the adhesive 47 with respect to the center of the first component 25. According to this structure, a portion of the impact transmitted from the end of the circuit board 6 is escaped (i.e., dispersed) to the second component 27 outside the adhesive 47 and it is possible to protect the adhesive 47. That is, the second components 27 can protect the protective portions (e.g., adhesives 47) protecting the corners 33a, 33b, 33c, and 33d. In this way, it is possible to further improve the impact resistance of the electronic apparatus 10.

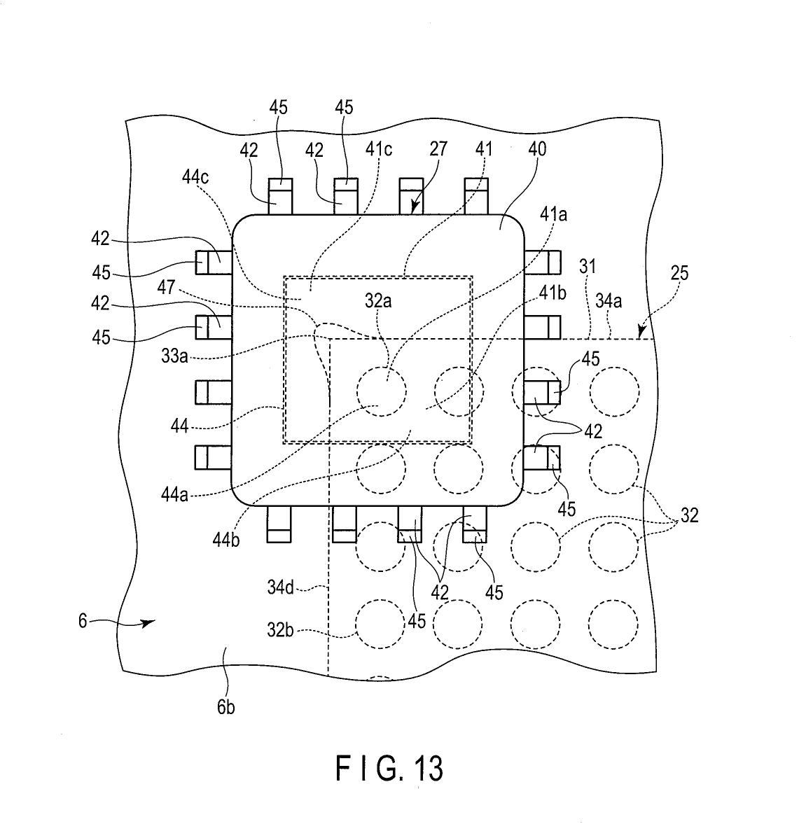

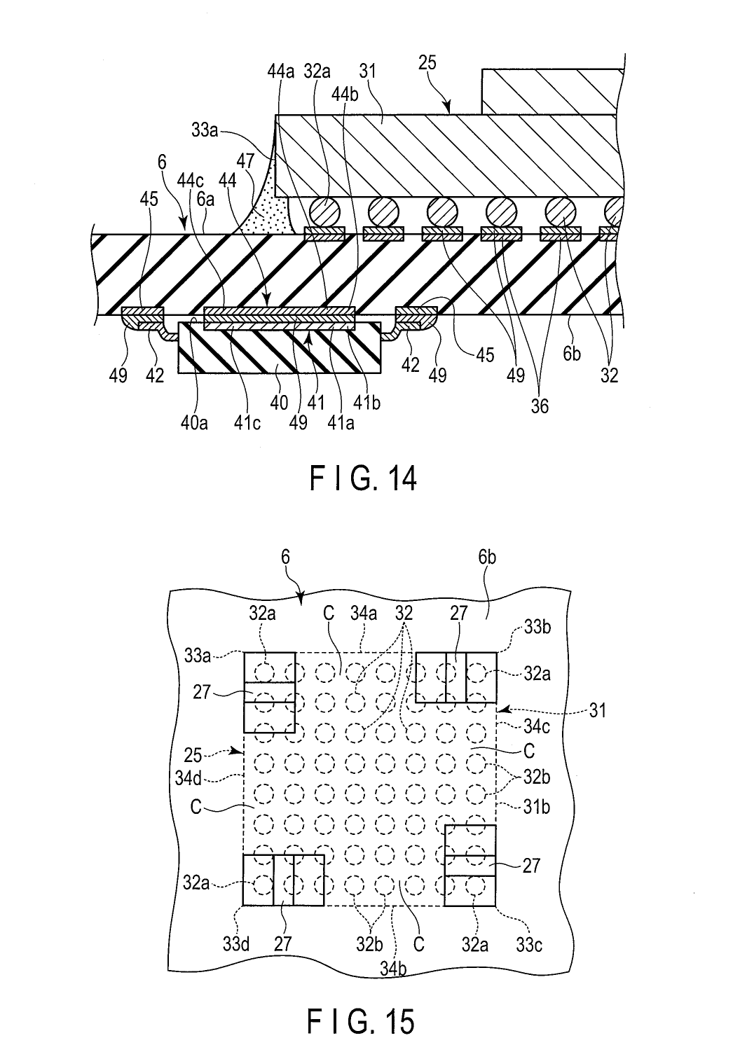

Next, a modification of this embodiment will be described with reference to FIGS. 13 and 14. As illustrated in FIGS. 13 and 14, in this modification, the first pad 44 includes a first portion 44a (i.e., first region), a second portion 44b (i.e., second region), and a third portion 44c (i.e., third region).

The first portion 44a is disposed on the back side of the first bump 32a. The second portion 44b is closer to the center of the first component 25 than the first portion 44a (i.e., the first bump 32a). The third portion 44c is disposed outside the first portion 44a (i.e., outside the first bump 32a) with respect to the first component 25. In this modification, a part of the third portion 44c is disposed outside the adhesive 47 with respect to the center of the first component 25.

In this modification, the first portion 44a is an example of a “first pad region”. The third portion 44c is an example of a “second pad region”. That is, the “first pad region” and the “second pad region” may form one pad as in this modification or two independent pads as in the second embodiment.

The first electrode 41 of the second component 27 is fixed across the first portion 44a, the second portion 44b, and the third portion 44c of the first pad 44. Therefore, the first electrode 41 includes a first portion 41a, a second portion 41b, and a third portion 41c.

The first portion 41a is disposed on the back side of the first bump 32a. The second portion 41b is closer to the center of the first component 25 than the first portion 41a. The third portion 41c is disposed outside the first portion 41a with respect to the center of the first component 25. In this modification, a part of the third portion 41c is fixed to the circuit board 6 outside the adhesive 47 with respect to the first component 25. The first electrode 41 covers, for example, the back sides of a plurality of bumps 32.

At least one second pad 45 and one second electrode 42 are disposed on the back side of the first component 25. At least one second pad 45 and one second electrode 42 are disposed outside the first bump 32a and the adhesive 47 with respect to the center of the first component 25.

According to this structure, similarly to the second embodiment, it is possible to improve the impact resistance of the electronic apparatus 10. In addition, in this modification, a portion of the first electrode 41 with a relatively large area is disposed outside the first bump 32a. According to this structure, it is possible to protect the first bump 32a at a high level.

### Third Embodiment

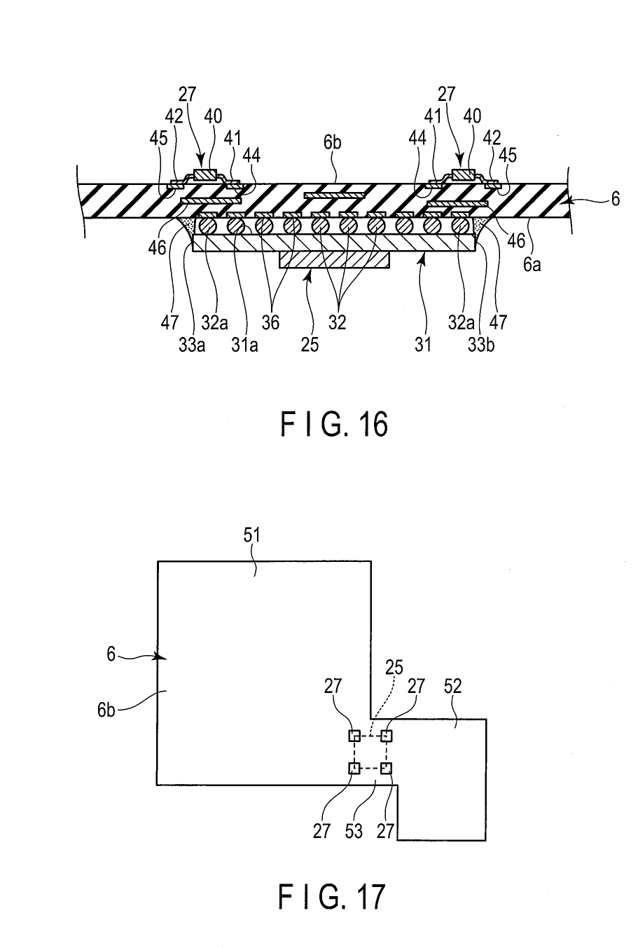

Next, an electronic apparatus 10 according to a third embodiment will be described with reference to FIGS. 15 and 16. In the third embodiment, components having the same or similar functions as those in the second embodiment are denoted by the same reference numerals and the description thereof will not be repeated. Structures other than the following structures are the same as those in the second embodiment.

In this embodiment, a second component 27 is, for example, a chip resistor, a capacitor, a transistor, or a diode and does not include a bottom electrode. The second component 27 includes a resin portion 40. The resin portion 40 includes a first end and a second end opposite to the first end. A first electrode 41 is provided at the first end of the resin portion 40. A second electrode 42 is provided at the second end of the resin portion 40. For example, the first electrode 41 and the second electrode 42 have substantially the same size.

The circuit board 6 includes a first pad 44 and a second pad 45. The first pad 44 is disposed on the back side of the first component 25. A portion of the second pad 45 is disposed outside the first bump 32a with respect to the center of the first component 25. A portion of the second pad 45 is disposed outside, for example, the adhesive 47. For example, the first pad 44 and the second pad 45 have substantially the same size.

According to this structure, similarly to the second embodiment, it is possible to improve the impact resistance of the electronic apparatus 10. For example, a chip resistance or capacitor used in this embodiment is generally cheaper than an electronic component with a bottom electrode. Therefore, according to this embodiment, it is possible to reduce the manufacturing costs of the electronic apparatus 10.

In all of the following embodiments and modifications, the second component 27 may have the bottom electrode as in the second embodiment or may not have the bottom electrode as in the third embodiment. In addition, the second component 27 with the bottom electrode and the second component 27 without the bottom electrode may be combined with each other.

### Fourth Embodiment

Next, an electronic apparatus 10 according to a fourth embodiment will be described with reference to FIG. 17. In the fourth embodiment, components having the same or similar functions as those in the second embodiment are denoted by the same reference numerals and the description thereof will not be repeated. Structures other than the following structures are the same as those in the second embodiment.

As illustrated in FIG. 17, a circuit board 6 includes a first region 51, a second region 52, and a third region 53. The third region 53 is disposed between the first region 51 and the second region 52 and is narrower than the first region 51 and the second region 52. Some second components 27 are provided in the third region 53.

According to this structure, similarly to the second embodiment, it is possible to improve the impact resistance of the electronic apparatus 10. In this embodiment, the second component 27 can reinforce a weak portion of the circuit board 6. This contributes to improving the impact resistance of the electronic apparatus 10.

### Fifth Embodiment

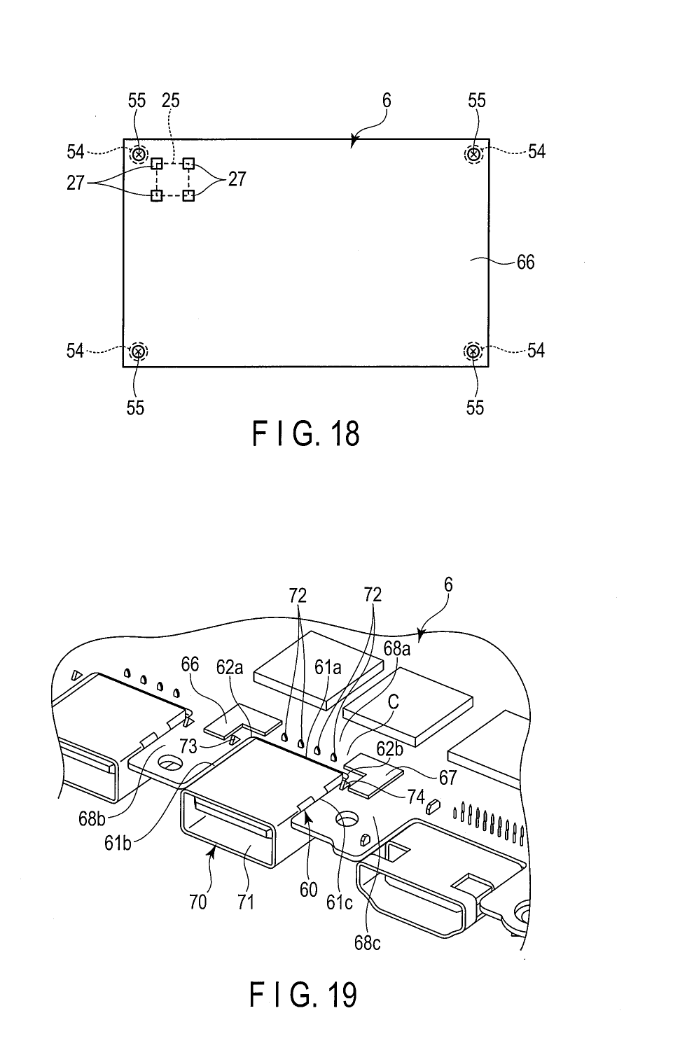

Next, an electronic apparatus 10 according to a fifth embodiment will be described with reference to FIG. 18. In the fifth embodiment, components having the same or similar functions as those in the second embodiment are denoted by the same reference numerals and the description thereof will not be repeated. Structures other than the following structures are the same as those in the second embodiment.

As illustrated in FIG. 18, a housing 14 includes supporting portions 54 that support a circuit board 6. The supporting portion 54 is, for example, a boss that is provided on the inner surface of the housing 14. The circuit board 6 is fixed to the supporting portions 54 by fixing members 55 (e.g., screws). In this embodiment, one second component 27 is disposed in the vicinity of the supporting portion 54.

According to this structure, similarly to the second embodiment, it is possible to improve the impact resistance of the electronic apparatus 10. A region of the circuit board 6 in the vicinity of the supporting portion 54 is likely to receive a load from the supporting portion 54. Therefore, when the second component 27 is provided in the vicinity of the supporting portion 54, the circuit board 6 can be locally protected by the second component 27. This contributes to improving the impact resistance of the electronic apparatus 10.

### Sixth Embodiment

Next, an electronic apparatus 10 according to a sixth embodiment will be described with reference to FIGS. 19 to 21. In the sixth embodiment, components having the same or similar functions as those in the second embodiment are denoted by the same reference numerals and the description thereof will not be repeated. Structures other than the following structures are the same as those in the second embodiment.

As illustrated in FIG. 19, a cutout 60 is provided at the end of a circuit board 6 according to this embodiment. The cutout 60 includes three sides 61a, 61b, and 61c and two corners 62a and 62b. The first side 61a (i.e., a first side, a first edge, or a first end) is disposed on the innermost part of the cutout 60. The first side 61a includes a first end and a second end opposite to the first end.

The second side 61b (i.e., a second side, a second edge, or a second end) extends from the first end of the first side 61a in a direction crossing (e.g., substantially perpendicular to) the first side 61a. The third side 61c (i.e., a third side, a third edge, or a third end) is opposite to the second side 61b. The third side 61c extends from the second end of the first side 61a in a direction crossing (e.g., a direction substantially perpendicular to) the first side 61a. The third side 61c is substantially parallel to, for example, the second side 61b.

The first corner 62a is provided at the intersection of the first side 61a and the second side 61b. The second corner 62b is provided at the intersection of the first side 61a and the third side 61c. That is, the first corner 62a and the second corner 62b are separately arranged on both sides of the first side 61a.

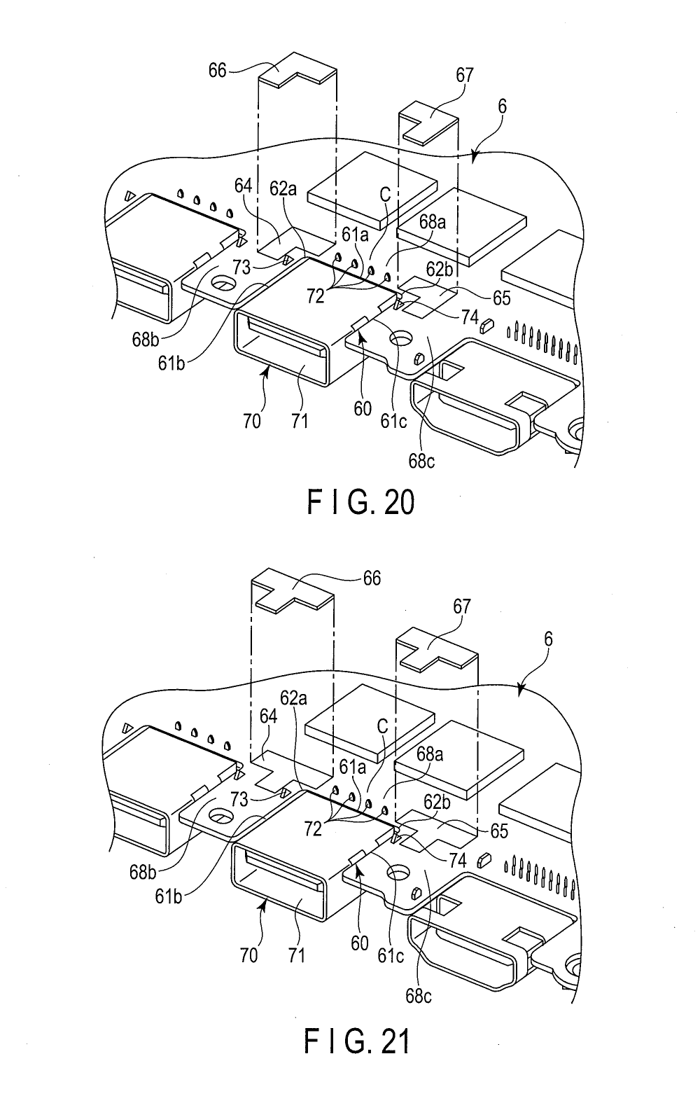

As illustrated in FIG. 20, the circuit board 6 includes a first pad 64 (i.e., a first conductive portion, a first connection portion, a first fixing portion, or a first metal portion) and a second pad 65 (i.e., a second conductive portion, a second connection portion, a second fixing portion, or a second metal portion). The first pad 64 is provided in the vicinity of the first corner 62a. The first pad 64 includes an L-shaped region (i.e., portion) arranged along the first corner 62a. The second pad 65 is provided in the vicinity of the second corner 62b. The second pad 65 includes an L-shaped region (i.e., portion) arranged along the second corner 62b.

In this embodiment, the first pad 64 and the second pad 65 have an L-shape. As illustrated in FIG. 21, the first pad 64 and the second pad 65 are not limited to the L-shape, but may have, for example, a T-shape or other shapes.

As illustrated in FIGS. 19 and 20, a first reinforcing component 66 (i.e., a first component, a first surface-mounted component, or a first reinforcing portion) is soldered to the first pad 64. The first reinforcing component 66 is mounted in the vicinity of the first corner 62a and is arranged along the edge of the cutout 60. The first reinforcing component 66 includes an L-shaped portion arranged along the first corner 62a.

A second reinforcing component 67 (i.e., a second component, a second surface-mounted component, or a second reinforcing portion) is soldered to the second pad 65. The second reinforcing component 67 is mounted in the vicinity of the second corner 62b and is arranged along the edge of the cutout 60. The second reinforcing component 67 includes an L-shaped portion arranged along the second corner 62b.

A gap C is provided between the first reinforcing component 66 and the second reinforcing component 67. The gap C is larger than, for example, the size of the first reinforcing component 66. The first reinforcing component 66 and the second reinforcing component 67 may be provided on the same surface of the circuit board 6, or they may be separately provided on the upper and lower surfaces.

In this embodiment, each of the first reinforcing component 66 and the second reinforcing component 67 is an L-shaped metal plate (i.e., metal portion). The first reinforcing component 66 and the second reinforcing component 67 are not limited to the L-shape, but may have, for example, a T-shape or other shapes. The first reinforcing component 66 and the second reinforcing component 67 are not limited to the metal plate, but may be electronic components (e.g., the second components 27), similarly to the second or third embodiment.

As illustrated in FIGS. 19 and 20, the circuit board 6 includes a first region 68a (i.e., first portion), a second region 68b (i.e., second portion), and a third region 68c (i.e., third portion). The first region 68a is arranged along the first side 61a of the cutout 60. The second region 68b protrudes from the first region 68a to the outside of the circuit board 6. The first corner 62a is disposed between the second region 68b and the first region 68a.

The third region 68c protrudes from the first region 68a to the outside of the circuit board 6. In other words, the cutout 60 is disposed between the second region 68b and the third region 68c. The second corner 62b is disposed between the third region 68c and the first region 68a.

As illustrated in FIGS. 19 and 20, a connector 70 is accommodated in the cutout 60. The connector 70 is an example of a “component” or an “external connection component”. The connector 70 is, for example, a USB connector. The “component” is not limited to the connector 70, but various components may be widely applied.

The connector 70 includes a main unit 71 (i.e., receiving unit) and first to third terminals 72, 73, and 74 protruding from the main unit 71. The main unit 71 is an example of a “body”. The main unit 71 is accommodated in the cutout 60. The housing 14 includes an opening 75 facing the connector 70 (see FIG. 4). The main unit 71 is exposed to the outside of the housing 14 through the opening 75 such that the user can access the main unit 71. An external component is connected to the connector 70.

As illustrated in FIGS. 19 and 20, a plurality of first terminals 72 are fixed to the first region 68a of the circuit board 6. In other words, the plurality of first terminals 72 are fixed to the circuit board 6 between the first reinforcing component 66 and the second reinforcing component 67. The plurality of first terminals 72 are arranged along the first side 61a of the cutout 60.

The second terminal 73 is fixed to the second region 68b of the circuit board 6. At least a portion of the second terminal 73 is disposed between the first reinforcing component 66 and the cutout 60 in a direction in which the first reinforcing component 66 and the second reinforcing component 67 are connected to each other. The third terminal 74 is fixed to the third region 68c of the circuit board 6. At least a portion of the third terminal 74 is disposed between the second reinforcing component 67 and the cutout 60 in the direction in which the first reinforcing component 66 and the second reinforcing component 67 are connected to each other.

According to this structure, it is possible to improve the impact resistance of the electronic apparatus 10.

When the cutout 60 is provided in the circuit board 6, the strength of a portion in the vicinity the cutout 60 is low. In this embodiment, the surface-mounted components (e.g., the reinforcing components 66 and 67) are provided along the edge of the cutout 60. According to this structure, it is possible to locally reinforce a weak portion of the circuit board 6. In this way, it is possible to improve the impact resistance of the electronic apparatus 10.

In this embodiment, the circuit board 6 includes the corners 62a and 62b. When impact is applied to the electronic apparatus 10, a defect, such as a crack, is likely to occur in the corners 62a and 62b. In this embodiment, the circuit board 6 includes the L-shaped pads 64 and 65 arranged along the corners 62a and 62b and the L-shaped surface-mounted components (e.g., the reinforcing components 66 and 67) fixed to the pads 64 and 65. In this way, it is possible to disperse stress concentration portions and reinforce the corners 62a and 62b on which stress is likely to be concentrated.

In particular, when the reinforcing components 66 and 67 are mounted on the L-shaped pads 64 and 65, the bonding area between the reinforcing components 66 and 67 and the circuit board 6 increases and bonding strength is high. Therefore, it is possible to reliably prevent the occurrence of a crack, as compared to, for example, screwing.

In this embodiment, the gap C is provided between the first reinforcing component 66 and the second reinforcing component 67. Therefore, impact input to the circuit board 6 can be dispersed to the inside of the circuit board 6 through the gap C. As a result, for example, stress is less likely to be concentrated on the corners 62a and 62b or the terminals 72, 73, and 74, as compared to a structure in which a large reinforcing component which surrounds the cutout 60 in three directions is provided. This contributes to improving the impact resistance of the electronic apparatus 10. In particular, when the gap C is larger than the size of the first reinforcing component 66, it is possible to reliably disperse stress. In this way, it is possible to further improve the impact resistance of the electronic apparatus 10.

In this embodiment, the first terminal 72 of the connector 70 is fixed to the circuit board 6 between the first reinforcing component 66 and the second reinforcing component 67. According to this structure, the gap C between the first reinforcing component 66 and the second reinforcing component 67 is effectively used. In this way, it is possible to achieve high-density mounting.

In this embodiment, a plurality of first terminals 72 are arranged along the first side 61a of the cutout 60. According to this structure, a region between the first reinforcing component 66 and the second reinforcing component 67 is effectively used. In this way, it is possible to achieve high-density mounting.

In this embodiment, the reinforcing components 66 and 67 are provided along the corners 62a and 62b of the cutout 60 in which an external connection component (e.g., the connector 70) exposed to the outside is accommodated. When an external component is connected, the user inserts the external component into the external connection component, such as a connector. Therefore, a large load is likely to be applied to a region of the circuit board 6 arranged around the external connection component. However, in this embodiment, the reinforcing components 66 and 67 are provided along the corners 62a and 62b to protect the circuit board 6. In this way, it is possible to further improve the impact resistance of the electronic apparatus 10 provided with the external connection component.

In this embodiment, the circuit board 6 includes the second region 68b and the third region 68c. The first corner 62a is disposed between the second region 68b and the first region 68a. The connector 70 includes the second terminal 73 fixed to the second region 68b.

As such, when the two terminals 72 and 73 are separately provided on both sides of the corner 62a, a load is likely to be concentrated on the corner 62a. As a result, the corner 62a is likely to be damaged. However, in this embodiment, the reinforcing component 66 is provided along the corner 62a to protect the corner 62a. In this way, it is possible to further improve the impact resistance of the electronic apparatus 10.

In this embodiment, at least a portion of the second terminal 73 is disposed between the first reinforcing component 66 and the cutout 60. In other words, the first reinforcing component 66 covers at least a portion of the second terminal 73 from the side opposite to the cutout 60. According to this structure, the first reinforcing component 66 can strongly reinforce a region between the second terminal 73 and the first terminal 72. In this way, it is possible to further improve the impact resistance of the electronic apparatus 10.

In this embodiment, each of the first reinforcing component 66 and the second reinforcing component 67 is an L-shaped metal plate. The reinforcing components 66 and 67 can be attached to the circuit board 6 together with other components of the circuit board by the surface mounting process. This contributes to simplifying a manufacturing process and reducing manufacturing costs.

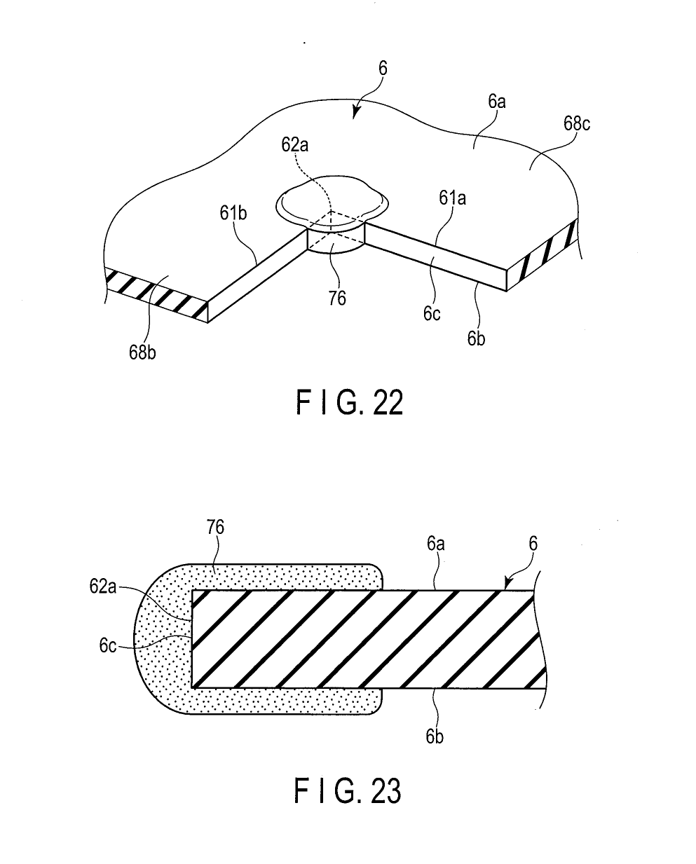

Next, a first modification of this embodiment will be described with reference to FIGS. 22 and 23. Structures other than the following structures are the same as those in the sixth embodiment.

As illustrated in FIGS. 22 and 23, the circuit board 6 includes a first surface 6a, a second surface 6b, and a third surface 6c. The second surface 6b is opposite to the first surface 6a. The third surface 6c extends between the first surface 6a and the second surface 6b in a direction crossing (e.g., a direction substantially perpendicular to) the first surface 6a and the second surface 6b. That is, the third surface 6c forms the thickness of the circuit board 6 and is a side surface of the circuit board 6.

As illustrated in FIGS. 22 and 23, an adhesive 76 (an adhesive portion or a reinforcing portion) is provided at each of the first corner 62a and the second corner 62b of the circuit board 6. For example, the adhesive 76 is formed by hardening a coated adhesive. The adhesive 76 is provided on at least the third surface 6c at the corners 62a and 62b. In this embodiment, the adhesive portion 76 is provided on the first surface 6a, the second surface 6b, and the third surface 6c at the corners 62a and 62b.

According to this structure, the adhesive 76 can disperse stress concentration points and a crack is less likely to occur at the corners 62a and 62b. This contributes to improving the impact resistance of the electronic apparatus 10.

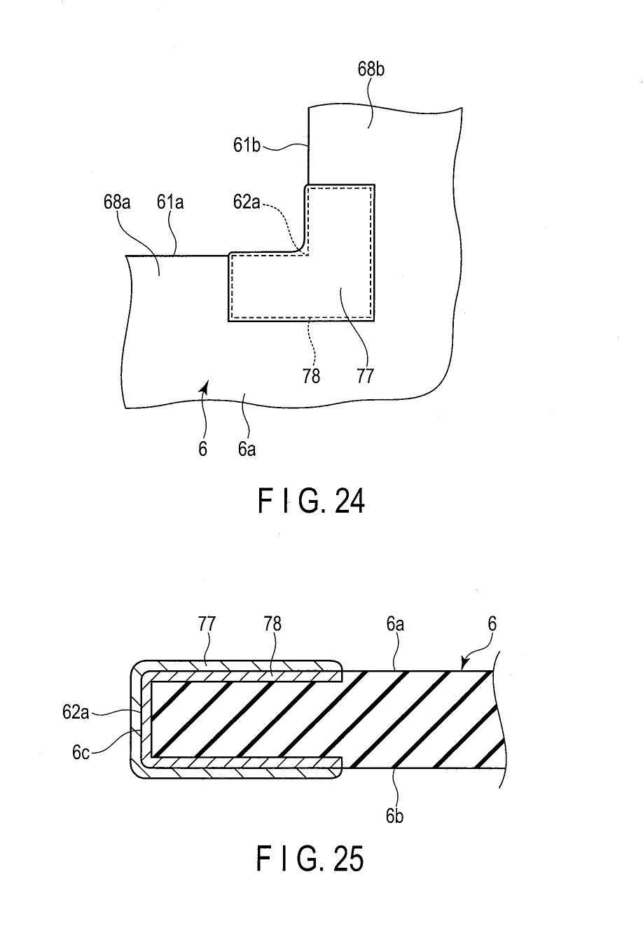

Next, a second modification of this embodiment will be described with reference to FIGS. 24 and 25. Structures other than the following structures are the same as those in the first modification.

As illustrated in FIGS. 24 and 25, a reinforcing portion 77 is provided at each of the first corner 62a and the second corner 62b of the circuit board 6. The reinforcing portion 77 is, for example, solder on the circuit board 6. The circuit board 6 includes a metal portion 78 (i.e., a pad or a metal surface portion) to which solder can be applied and in which the reinforcing portion 77 will be provided. The reinforcing portion 77 is provided on at least the third surface 6c at the corners 62a and 62b. In this embodiment, the reinforcing portion 77 is provided on the first surface 6a, the second surface 6b, and the third surface 6c at the corners 62a and 62b.

According to this structure, the reinforcing portion 77 can disperse stress concentration points and a crack is less likely to occur at the corners 62a and 62b. This contributes to improving the impact resistance of the electronic apparatus 10. In addition, the first modification and the second modification can be applied to a circuit board 6 in which the reinforcing components 66 and 67 are not provided. That is, the adhesive portion 76 or the reinforcing portion 77 can independently improve the impact resistance of the electronic apparatus 10.

### Seventh Embodiment

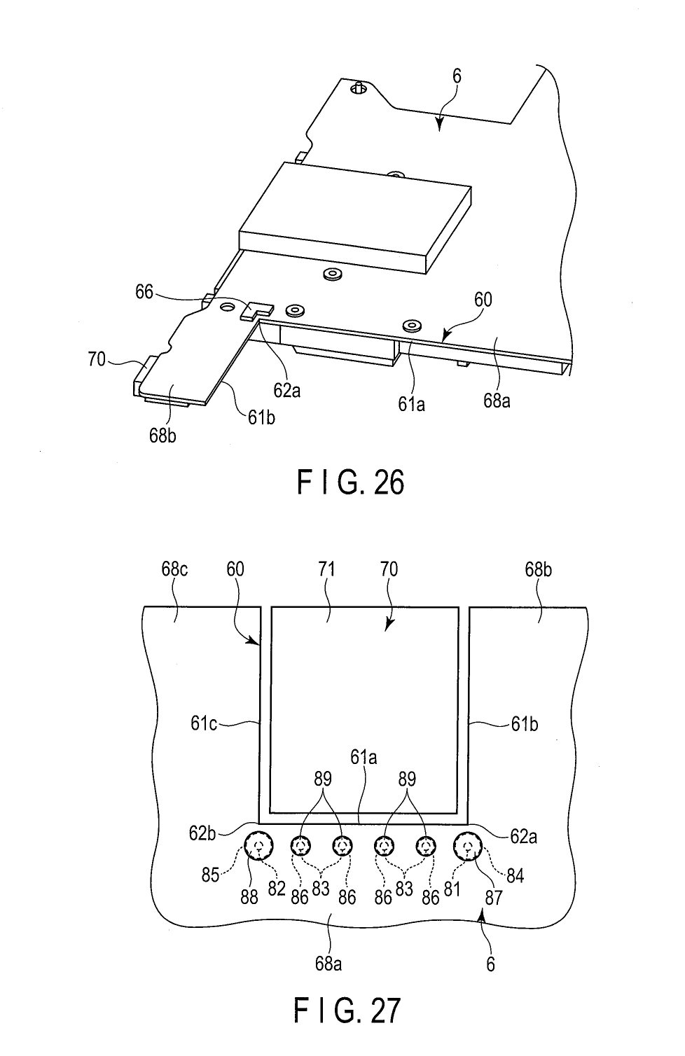

Next, an electronic apparatus 10 according to a seventh embodiment will be described with reference to FIG. 26. In the seventh embodiment, components having the same or similar functions as those in the second and sixth embodiments are denoted by the same reference numerals and the description thereof will not be repeated. Structures other than the following structures are the same as those in the sixth embodiment.

As illustrated in FIG. 26, a circuit board 6 includes a cutout 60. In other words, the circuit board 6 includes a first region 68a (i.e., first portion) and a second region 68b (i.e., second portion) which protrudes from the first region 68a. A corner 62a is provided between the first region 68a and the second region 68b. A connector 70 is provided in the second region 68b. The connector 70 is an example of a “component” or an “external connection component”. The component provided in the second region 68b is not limited to the connector.

In this embodiment, a reinforcing component 66 is provided along the cutout 60. The reinforcing component 66 is provided in the vicinity of the corner 62a. The circuit board 6 includes a pad 64. The pad 64 includes an L-shaped portion arranged along the corner 62a. The reinforcing component 66 includes an L-shaped portion arranged along the corner 62a and is fixed to the pad 64.

According to this structure, similarly to the sixth embodiment, it is possible to improve the impact resistance of the electronic apparatus 10. In addition, the reinforcing component 66 may be an L-shaped or T-shaped metal plate as in the sixth embodiment or an electronic component 27 (i.e., second component 27) as in the second or third embodiment.

### Eighth Embodiment

Next, an electronic apparatus 10 according to an eighth embodiment will be described with reference to FIG. 27. In the eighth embodiment, components having the same or similar functions as those in the second and sixth embodiments are denoted by the same reference numerals and the description thereof will not be repeated. Structures other than the following structures are the same as those in the sixth embodiment.

As illustrated in FIG. 27, a circuit board 6 includes a cutout 60. A main portion 71 of the connector 70 is accommodated in the cutout 60. The connector 70 is an example of a “component” or an “external connection component”. The component accommodated in the cutout 60 is not limited to the connector.

The connector 70 includes first to third terminals 81, 82, and 83. The first terminal 81 is provided in the vicinity of the first corner 62a. The second terminal 82 is provided in the vicinity of the second corner 62b. A plurality of third terminals 83 are arranged between the first terminal 81 and the second terminal 82.

As illustrated in FIG. 27, the circuit board 6 includes first to third lands 84, 85, and 86. The first land 84 corresponds to the first terminal 81 and includes a hole into which the first terminal 81 is inserted. A first solder portion 87 (i.e., a first fixing portion or a first bonding portion) which fixes the first terminal 81 to the circuit board 6 is provided in the first land 84.

The second land 85 corresponds to the second terminal 82 and includes a hole into which the second terminal 82 is inserted. A second solder portion 88 (i.e., a second fixing portion or a second bonding portion) which fixes the second terminal 82 to the circuit board 6 is provided in the second land 85. The third land 86 corresponds to the third terminal 83 and includes a hole into which the third terminal 83 is inserted. A third solder portion 89 (i.e., a third fixing portion or a third bonding portion) which fixes the third terminal 83 to the circuit board 6 is provided in the third land 86.

As illustrated in FIG. 27, the area of the first land 84 and the second land 85 is larger than that of the third land 86. The first solder portion 87 and the second solder portion 88 are larger than the third solder portion 89. The amount of solder in the first solder portion 87 and the second solder portion 88 is greater than the amount of solder in the third solder portion 89 and the bonding strength of the first solder portion 87 and the second solder portion 88 is stronger than that of third solder portion 89.

According to this structure, the first solder portion 87 and the second solder portion 88 can protect the corners 62a and 62b. In this way, it is possible to improve the impact resistance of the electronic apparatus 10.

### Ninth Embodiment

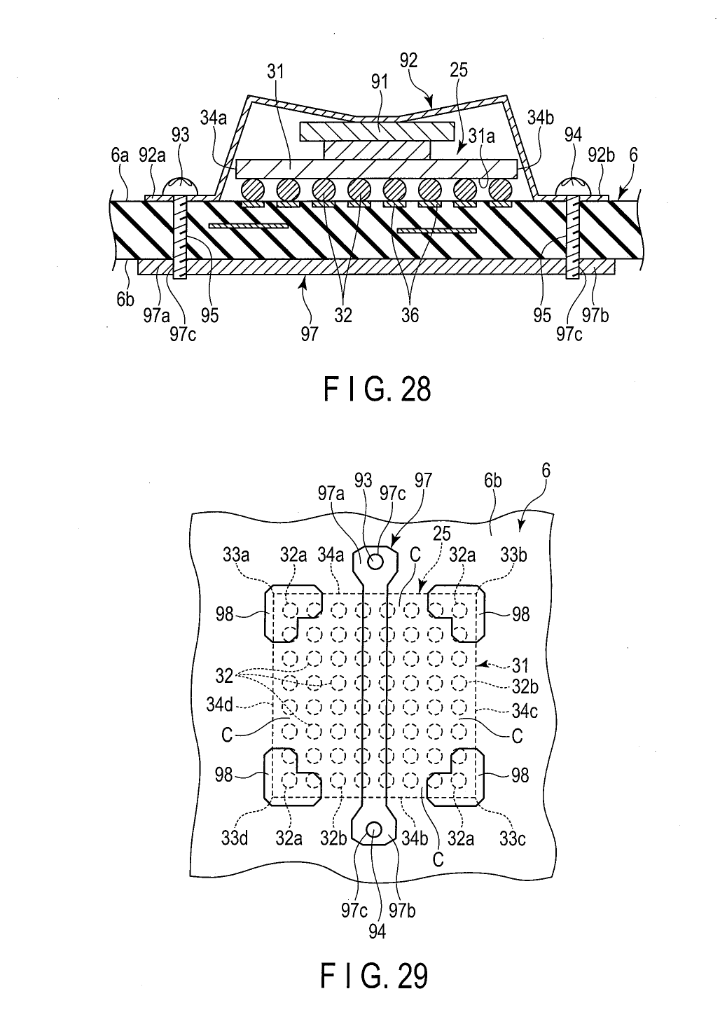

Next, an electronic apparatus 10 according to a ninth embodiment will be described with reference to FIGS. 28 to 31. In the ninth embodiment, components having the same or similar functions as those in the second embodiment are denoted by the same reference numerals and the description thereof will not be repeated. Structures other than the following structures are the same as those in the second embodiment.

As illustrated in FIGS. 28 and 29, a heat-generating component 25 is mounted on a first surface 6a of a circuit board 6. The heat-generating component 25 is an example of a “component”, a “surface-mounted component”, a “heating element”, or a “first component”. The heat-generating component 25 is supplied with power and generates heat. The heat-generating component 25 includes four corners 33a, 33b, 33c, and 33d and four sides 34a, 34b, 34c, and 34d. An example of the heat-generating component 25 is a surface-mounted component including a package 31 and a plurality of bumps 32 on a bottom surface 31a of the package 31.

As illustrated in FIG. 28, the electronic apparatus 10 includes a heat receiving portion 91 and a pressing portion 92. The heat receiving portion 91 (i.e., a heat receiving member, a heat dissipating portion, or a heat dissipating member) faces the circuit board 6 with the heat-generating component 25 interposed therebetween and is thermally connected to the heat-generating component 25. A thermally-conductive grease or a thermally-conductive sheet is provided between the heat receiving portion 91 and the heat-generating component 25. The pressing portion 92 (i.e., pressing member) faces the heat receiving portion 91 and presses the heat receiving portion 91 to the heat-generating component 25. In this way, the thermal connection between the heat receiving portion 91 and the heat-generating component 25 is improved.

As illustrated in FIG. 28, two supporting portions 93 and 94 (i.e., supporters, fixing portions, or attachment portions) are provided in the circuit board 6. In this embodiment, holes 95 into which the first supporting portion 93 and the second supporting portion 94 are inserted are provided in the circuit board 6. The first supporting portion 93 and the second supporting portion 94 are inserted into the holes 95 and pass through the circuit board 6. The first supporting portion 93 and the second supporting portion 94 are, for example, screws. The first supporting portion 93 and the second supporting portion 94 are separately arranged on both sides of the heat-generating component 25.

The pressing portion 92 is fixed to the circuit board 6 by the first supporting portion 93 and the second supporting portion 94. Specifically, the pressing portion 92 includes a first end 92a which is supported (i.e., fixed to) by the first supporting portion 93 and a second end 92b which is supported (i.e., fixed to) by the second supporting portion 94. The pressing portion 92 is elastically deformed between the first end 92a and the second end 92b and applies a pressing force to the heat receiving portion 91.

As illustrated in FIG. 29, in this embodiment, the first supporting portion 93 is away from the vicinities of the first corner 33a and the second corner 33b. The first supporting portion 93 is closer to the center of the first side 34a than to the first corner 33a and the second corner 33b. For example, the first supporting portion 93 is disposed substantially in the vicinity of the center of the first side 34a.

Similarly, the second supporting portion 94 is away from the vicinities of the third corner 33c and the fourth corner 33d. The second supporting portion 94 is closer to the center of the second side 34b than to the third corner 33c and the fourth corner 33d. For example, the second supporting portion 94 is disposed substantially in the vicinity of the center of the second side 34b.

As illustrated in FIG. 29, a first reinforcing portion 97 and a plurality of second reinforcing portions 98 are provided on the second surface 6b of the circuit board 6. The first reinforcing portion 97 and the second reinforcing portion 98 are individual portions. The second reinforcing portions 98 are individual portions. In this embodiment, each of the first reinforcing portion 97 and the second reinforcing portion 98 is a metal plate. An example of the first reinforcing portion 97 is a screw-fastened back plate. An example of the second reinforcing portion 98 is a soldering plate. The second reinforcing portion 98 is an example of a “surface-mounted component”, a “second component”, or a “reinforcing component”.

As illustrated in FIG. 29, the size of the first reinforcing portion 97 is larger than that of the heat-generating component 25. The length of the first reinforcing portion 97 is longer than that of one side (e.g., the third side 34c or the fourth side 34d) of the heat-generating component 25. The first reinforcing portion 97 includes a first end 97a and a second end 97b opposite to the first end 97a. Each of the first end 97a and the second end 97b include an insertion hole 97c. An example the insertion hole 97c is a screw hole.

The first end 97a is disposed substantially in the vicinity of the center of the first side 34a of the heat-generating component 25. The first supporting portion 93 is fixed to the insertion hole 97c of the first end 97a. In this way, the first end 97a is supported by the first supporting portion 93. The second end 97b is disposed substantially in the vicinity of the center of the second side 34b of the heat-generating component 25. The second supporting portion 94 is fixed to the insertion hole 97c of the second end 97b. In this way, the second end 97b is supported by the second supporting portion 94. That is, the first reinforcing portion 97 is fixed to the circuit board 6 by, for example, screws.

The first reinforcing portion 97 is disposed on the back side of the heat-generating component 25 so as to be across substantially the center of the first side 34a and substantially the center of the second side 34b. That is, the first reinforcing portion 97 includes a part which is disposed on the back side of substantially the center of the first side 34a and a part which is disposed on the back side of substantially the center of the second side 34b. The first reinforcing portion 97 is disposed on the back side of the pressing portion 92. The first reinforcing portion 97 faces the pressing portion 92 with the heat-generating component 25 interposed therebetween. The first reinforcing portion 97 includes a part which is disposed on the back side of substantially the center of, for example, the heat-generating component 25.

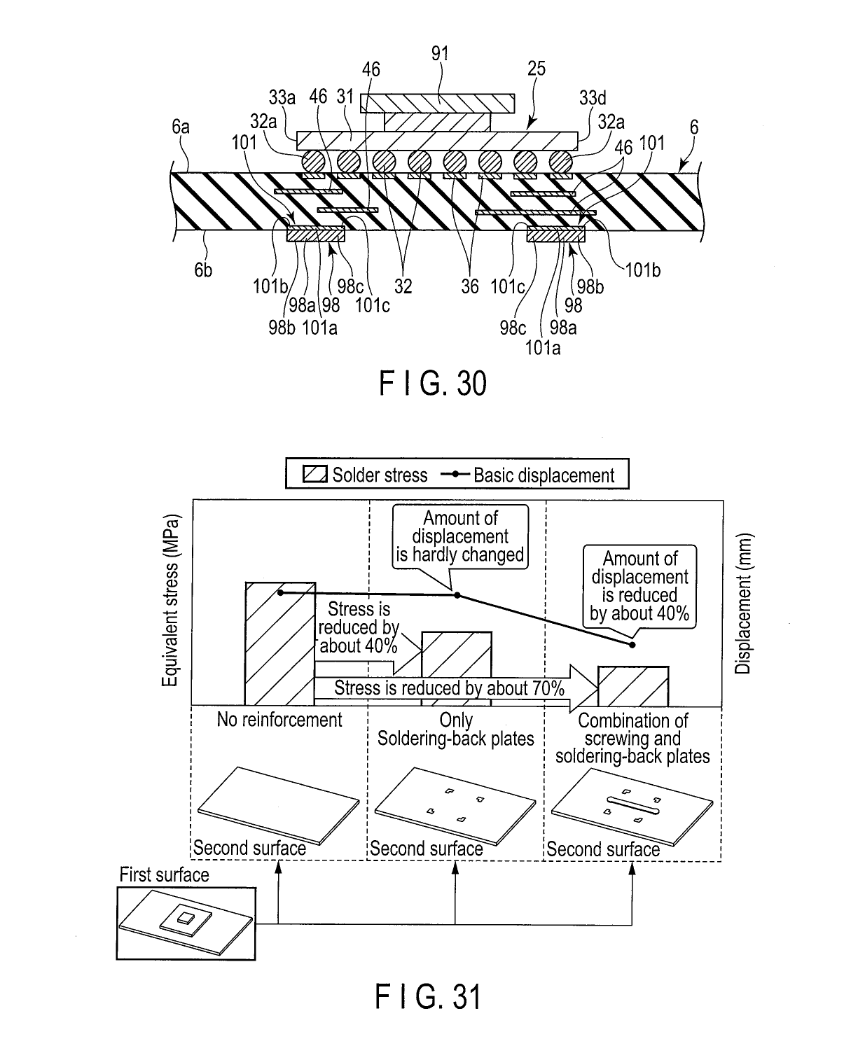

As illustrated in FIG. 30, the circuit board 6 includes pads 101 (i.e., conductive portions, connection portions, fixing portions, or metal portions) which are provided on the back side of four corners 33a, 33b, 33c, and 33d of the heat-generating component 25. The pad 101 includes a first portion 101a (i.e., first region), a second portion 101b (i.e., second region), and a third portion 101c (i.e., third region). The first portion 101a is disposed on the back side of the first bump 32a of the heat-generating component 25. The second portion 101b is disposed outside the first portion 101a with respect to the center of the heat-generating component 25. The third portion 101c is disposed closer to the center of the heat-generating component 25 than the first portion 101a. The pad 101 has an L-shape which is substantially the same as that of the second reinforcing portion 98.

As illustrated in FIG. 29, the second reinforcing portions 98 have, for example, an L-shaped along one of the corners 33a, 33b, 33c, and 33d. The four second reinforcing portions 98 are separately disposed on the back side of the four corners 33a, 33b, 33c, and 33d of the heat-generating component 25.

As illustrated in FIG. 30, the second reinforcing portion 98 is fixed to the first to third portions 101a, 101b, and 101c of the pad 101 and is mounted on the second surface 6b of the circuit board 6. The second reinforcing portions 98 are disposed on the back side of the corners 33a, 33b, 33c, and 33d. The second reinforcing portion 98 includes a first portion 98a, a second portion 98b, and a third portion 98c.

The first portion 98a is disposed on the back side of the first bump 32a of the heat-generating component 25. The second portion 98b is disposed outside the first portion 98a with respect to the heat-generating component 25. The third portion 98c is disposed closer to the center of the heat-generating component 25 than the first portion 98a.

As illustrated in FIG. 30, a wiring pattern 46 is provided between the second reinforcing portion 98 and the first surface 6a of the circuit board 6. That is, a portion of the wiring pattern 46 is disposed between the second reinforcing portion 98 and the first bump 32a.

According to this structure, it is possible to improve the impact resistance of the electronic apparatus 10.

When the reinforcing portions are provided at the corners 33a, 33b, 33c, and 33d of the heat-generating component 25, the strength (i.e., resistance) of the circuit board 6 against a dynamic load (e.g., vibration or impact) is improved, but the strength thereof against a static load is not sufficiently improved. Therefore, for example, when the pressing portion 92 is provided on the circuit board 6 and a constant static load is applied to the circuit board 6, it is preferable to provide a reinforcing portion for improving the strength of the circuit board 6.

In this embodiment, the first reinforcing portion 97 is provided on the second surface 6b of the circuit board 6 and is disposed on the back side of the heat-generating component 25 so as to be across the first side 34a and the second side 34b. The second reinforcing portions 98 are provided on the second surface 6b of the circuit board 6 and include parts which are disposed on the back side of the corners 33a, 33b, 33c, and 33d. In this way, the strength (i.e., resistance) of the circuit board 6 against a static load can be improved by the first reinforcing portion 97 and the strength (i.e., resistance) of the circuit board 6 against a dynamic load can be improved by the second reinforcing portion 98. As a result, it is possible to improve the resistance of the electronic apparatus 10 to an impact and a static load.

For example, the reinforcing portions for the static load from the pressing portion 92 need to be rigidly fixed to the circuit board 6 and involve supporting portions (e.g., fixing portions) passing through the circuit board 6. The following method is considered. The supporting portions of the reinforcing portions are provided in the vicinities of the corners 33a, 33b, 33c, and 33d of the heat-generating component 25 to protect the corners 33a, 33b, 33c, and 33d (i.e., first bumps 32a) of the heat-generating component 25 which are most likely to be damaged.

However, in general, wiring patterns are more likely to be concentrated on the vicinities of the corners 33a, 33b, 33c, and 33d of the heat-generating component 25 than on the centers of the sides 34a, 34b, 34c, and 34d. Therefore, when the supporting portions passing through the circuit board 6 are provided in the vicinities of the corners 33a, 33b, 33c, and 33d of the heat-generating component 25, the wiring layout of the heat-generating component 25 is largely restricted and it is difficult to achieve high-density mounting.

In this embodiment, the supporting portions 93 and 94 passing through the circuit board 6 are closer to the center of the first side 34a than to the first corner 33a. The first reinforcing portion 97 is fixed to the supporting portions 93 and 94 and is disposed on the back side of the heat-generating component 25 across the first side 34a and the second side 34b.

That is, in this embodiment, the supporting portions 93 and 94 passing through the circuit board 6 are arranged close to the centers of sides 34a and 34b of the heat-generating component 25 with a relatively small number of wiring lines. In this way, flexibility in the wiring layout in the vicinities of the corners 33a, 33b, 33c, and 33d of the heat-generating component 25 increases and it is possible to achieve high-density mounting.

The second reinforcing portions 98 are provided separately from the first reinforcing portion 97 at the corners 33a, 33b, 33c, and 33d of the heat-generating component 25 where the supporting portions 93 and 94 are not provided and are not sufficiently protected. Since the second reinforcing portions 98 are provided, it is possible to reinforce the corners 33a, 33b, 33c, and 33d of the heat-generating component 25 on which stress is most likely to be concentrated. Therefore, it is possible to improve the impact resistance of the electronic apparatus 10.

The second reinforcing portions 98 are surface-mounted components which are fixed to the second surface 6b of the circuit board 6. Therefore, the wiring pattern 46 can be provided at the position where the second reinforcing portion 98 is provided in the circuit board 6. In this embodiment, the wiring pattern 46 is provided between the second reinforcing portion 98 and the first surface 6a of the circuit board 6. According to this structure, flexibility in the wiring layout is further increased and it is possible to achieve high-density mounting.

In this embodiment, the pressing portion 92 includes the first end 92a supported by the first supporting portion 93 and the second end 92b supported by the second supporting portion 94, is elastically deformed between the first end 92a and the second end 92b, and applies a pressing force to the heat receiving portion 91. The first reinforcing portion 97 includes the first end 97a supported by first supporting portion 93 and the second end 97b supported by the second supporting portion 94 and is disposed on the back side of the pressing portion. According to this structure, the first reinforcing portion 97 can reliably receive the pressing force applied from the pressing portion 92 to the circuit board 6.

In this embodiment, the first supporting portion 93 and the second supporting portion 94 are separately provided on both sides of the heat-generating component 25. According to this structure, the first reinforcing portion 97 can reliably reinforce the back side of the heat-generating component 25 and it is easy to prevent a defect in the heat-generating component 25 due to the bending of the circuit board 6 by the pressing portion 92.

In this embodiment and the following modifications, the first supporting portion 93 and the second supporting portion 94 fix the pressing portion 92, but the embodiments are not limited thereto. The first supporting portion 93 and the second supporting portion 94 may fix other members, or no member may be fixed by the first supporting portion 93 and the second supporting portion 94.

In this embodiment, the second reinforcing portion 98 is a metal plate. The second reinforcing portion 98 can be mounted together with other components on the circuit board 6 by the surface mounting process. This contributes to simplifying a manufacturing process and reducing manufacturing costs. In this embodiment, the second reinforcing portions 98 have an L-shape along one of the corners 33a, 33b, 33c, and 33d of the heat-generating component 25. According to this structure, it is possible to protect the corners 33a, 33b, 33c, and 33d of the heat-generating component 25 at a higher level and further improve the impact resistance of the electronic apparatus 10.

In this embodiment, the pad 101 includes the first portion 101a which is disposed on the back side of the first bump 32a among a plurality of bumps 32 and the second portion 101b which is disposed outside the first bump 32a. The second reinforcing portion 98 is fixed to the first portion 101a and the second portion 101b of the pad 101.

According to this structure, the second reinforcing portion 98 can receive a stress wave traveling from the end of the circuit board 6 to the heat-generating component 25 at the outside of the first bump 32a. In this way, it is possible to shift a stress concentration point to the outside of the first bump 32a. Therefore, it is possible to reduce the load of the first bump 32a on which stress is most likely to be concentrated and thus improve impact resistance.

Similarly to the second or third embodiment, the second reinforcing portion 98 may be an electronic component 27, instead of the metal plate. That is, the circuit board 6 may include a first pad region which is disposed on the back side of the heat-generating component 25 and a second pad region which is disposed outside the first bump 32a with respect to the center of the heat-generating component 25. The second reinforcing portion 98 may be fixed to the first pad region and the second pad region.

FIG. 31 illustrates an example of the operation simulation result of this embodiment. As illustrated in the center column of FIG. 31, when the second reinforcing portions 98 are provided, equivalent stress applied to solder during an impact is reduced by, for example, about 40%. On the other hand, even when the second reinforcing portions 98 are provided, strength against a static load is not sufficiently improved, and the amount of displacement (i.e., the amount of bending) by a static load is hardly changed.

As illustrated in the right column of FIG. 31, when the first reinforcing portion 97 is provided in addition to the second reinforcing portions 98, equivalent stress applied to solder during an impact is reduced by, for example, about 70% and the amount of displacement (i.e., the amount of bending) by a static load is reduced by about 40%. As can be seen from this result, a combination of the first reinforcing portion 97 and the second reinforcing portions 98 is effective in improving the resistance of the electronic apparatus 10 to both a static load and a dynamic load.

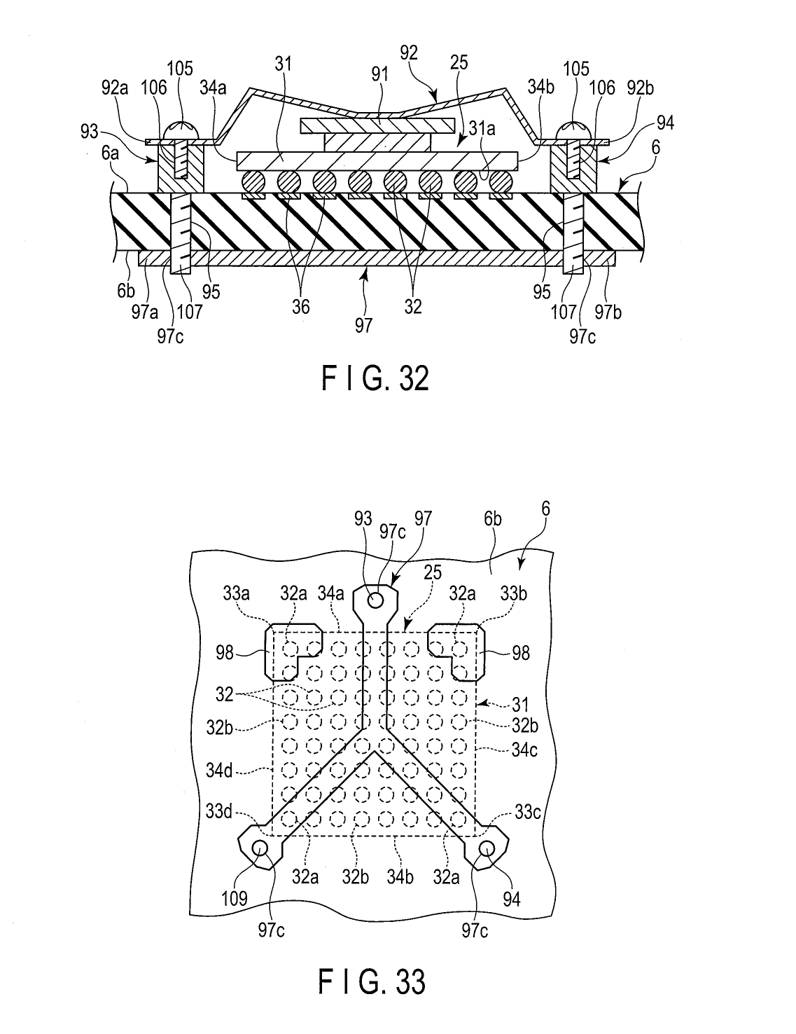

Next, a first modification of this embodiment will be described with reference to FIG. 32. Structures other than the following structures are the same as those in the ninth embodiment.

As illustrated in FIG. 32, a first supporting portion 93 and a second supporting portion 94 are provided on the circuit board 6. In this modification, the first supporting portion 93 and the second supporting portion 94 are studs supporting the pressing portion 92. The first supporting portion 93 and the second supporting portion 94 include, for example, screw holes 106 into which screws 105 are inserted to fix the pressing portion 92.

In this modification, holes 95 into which the first supporting portion 93 and the second supporting portion 94 are inserted are provided in the circuit board 6. The first supporting portion 93 and the second supporting portion 94 are inserted into the holes 95 and pass through the circuit board 6. The first supporting portion 93 and the second supporting portion 94 include engaging portions 107 fixed to a first reinforcing portion 97. The engaging portion 107 is, for example, a screw portion. When the engaging portions 107 are inserted into insertion holes 97c of the first reinforcing portion 97, the first reinforcing portion 97 is supported by the first supporting portion 93 and the second supporting portion 94.

According to this structure, similarly to the ninth embodiment, it is possible to improve the resistance of the electronic apparatus 10 to both an impact and a static load.

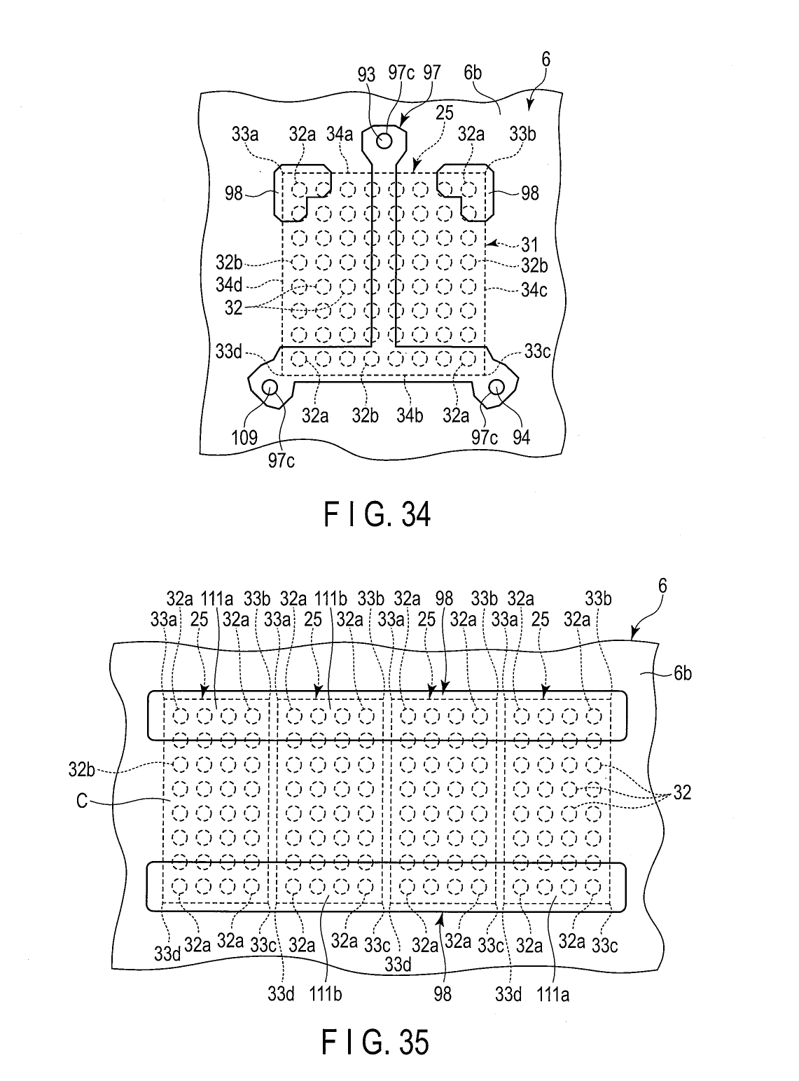

Next, second and third modifications of this embodiment will be described with reference to FIGS. 33 and 34. Structures other than the following structures are the same as those in the ninth embodiment.

FIG. 33 illustrates a first reinforcing portion 97 and second reinforcing portions 98 according to the second modification. FIG. 34 illustrates a first reinforcing portion 97 and second reinforcing portions 98 according to the third modification. A circuit board 6 according to each of the second and third modifications includes a third supporting portion 109 and a hole 95 into which the third supporting portion 109 is inserted. The third supporting portion 109 is inserted into the hole portion 95 and passes through the circuit board 6. A pressing portion 92 and the first reinforcing portion 97 are fixed to first to third supporting portions 93, 94, and 109 and are supported by the first to third supporting portions 93, 94, and 109.

The first supporting portion 93 is disposed in the vicinity of substantially the center of the first side 34a of the heat-generating component 25. The second supporting portion 94 is disposed in the vicinity of the third corner 33c of the heat-generating component 25. The second supporting portion 94 is disposed outside the first bump 32a with respect to the center of the first component 25. The third supporting portion 109 is disposed in the vicinity of the fourth corner 33d of the heat-generating component 25. The third supporting portion 109 is disposed outside the first bump 32a with respect to the center of the first component 25.

In this way, a stress wave traveling from the end of the circuit board 6 to the third and fourth corners 33c and 33d of the first component 25 is transmitted to the second supporting portion 94 and the third supporting portion 109 prior to the first bumps 32a. In this way, a portion of the impact can be escaped (i.e., dispersed) to the second supporting portion 94 and the third supporting portion 109. Therefore, in this modification, the second reinforcing portion 98 does not need to be provided at the third corner 33c and the fourth corner 33d.

The first reinforcing portion 97 is fixed to the first to third supporting portions 93, 94, and 109 and is disposed on the back side of the heat-generating component 25 across substantially the centers of the first side 34a and the second side 34b. A part of the first reinforcing portion 97 is disposed on the back side of substantially the center of the heat-generating component 25. The second reinforcing portions 98 are disposed on the back side of the corners 33a and 33b of the heat-generating component 25 where the first to third supporting portions 93, 94, and 109 are not provided.

According to this structure, similarly to the ninth embodiment, it is possible to improve the impact resistance of the electronic apparatus 10 and the strength thereof against a static load. In addition, at the corners 33a and 33b where the second reinforcing portion 98 is provided, the wiring layout of the heat-generating component 25 is not largely restricted. In this way, it is possible to achieve high-density mounting.

### Tenth Embodiment

Next, an electronic apparatus 10 according to a tenth embodiment will be described with reference to FIG. 35. In the tenth embodiment, components having the same or similar functions as those in the second and ninth embodiments are denoted by the same reference numerals and the description thereof will not be repeated. Structures other than the following structures are the same as those in the second embodiment.

As illustrated in FIG. 35, a plurality of components 25 are provided on a first surface 6a of a circuit board 6 so as to be adjacent to each other (i.e., so as to be arranged in a line). Reinforcing components 98 are provided on a second surface 6b of the circuit board 6. The reinforcing component 98 may be the electronic component 27 as in the second and third embodiments or the metal plate as in the sixth or ninth embodiment. The reinforcing components 98 are fixed to pads 101 on the second surface 6b of the circuit board 6 and are surface-mounted on the second surface 6b.

As illustrated in FIG. 35, in this embodiment, the reinforcing components 98 extend on the back side of the plurality of components 25. That is, the reinforcing component 98 according to this embodiment includes a first portion 111a which is disposed on the back side of one component 25 and a second portion 111b which is disposed on the back side of the other components 25. In other words, a reinforcing portion which is disposed on the back side of one component 25 and a reinforcing portion which is disposed on the back side of the other components 25 are integrally formed.

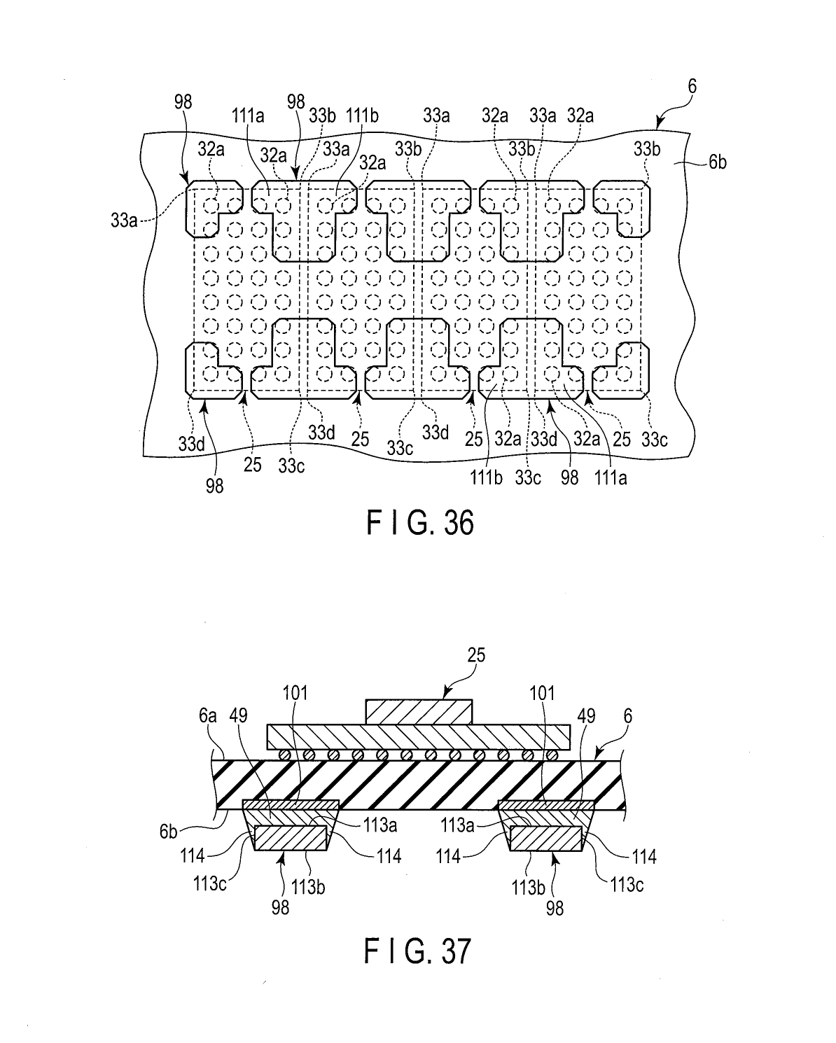

According to this structure, similarly to the second embodiment, it is possible to improve the impact resistance of the electronic apparatus 10. In addition, according to this embodiment, since the plurality of components 25 can be protected by a small number of reinforcing components 98, it is possible to reduce manufacturing costs. FIG. 36 illustrates a modification of this embodiment. As illustrated in the modification, the size or shape of the reinforcing component 98 is not particularly limited.

### Eleventh Embodiment

Next, an electronic apparatus 10 according to an eleventh embodiment will be described with reference to FIG. 37. In the eleventh embodiment, components having the same or similar functions as those in the second and ninth embodiments are denoted by the same reference numerals and the description thereof will not be repeated. Structures other than the following structures are the same as those in the second embodiment.

As illustrated in FIG. 37, a component 25 is provided on a first surface 6a of a circuit board 6. Reinforcing components 98 are provided on a second surface 6b of the circuit board 6. The reinforcing component 98 is a metal plate.

The reinforcing component 98 includes a first surface 113a, a second surface 113b, and a third surface 113c. The first surface 113a faces the pad 101. The second surface 113b is opposite to the first surface 113a and is exposed to the outside. The third surface 113c extends between the first surface 113a and the second surface 113b in a direction crossing (e.g., substantially perpendicular to) the first surface 113a and the second surface 113b. That is, the third surface 113c is the side surface of a second component 27.

In this embodiment, a plated layer is provided on the first surface 113a, the second surface 113b, and the third surface 113c. That is, each reinforcing component 98 is punched out in an L-shape from, for example, a plate-shaped material and plating is performed on the first surface 113a, the second surface 113b, and the third surface 113c.

According to this structure, similarly to the second embodiment, it is possible to improve the impact resistance of the electronic apparatus 10. In addition, in this embodiment, since the plated layer is provided on the third surface 113c, solder is melted and spread on the third surface 113c. Therefore, as illustrated in FIG. 37, a fillet 114 is formed between the third surface 113c of the reinforcing component 98 and the pad 101. According to this structure, the reinforcing component 98 is rigidly fixed to the circuit board 6 by the fillet 114 and the reliability of the electronic apparatus 10 is improved.

### Twelfth Embodiment

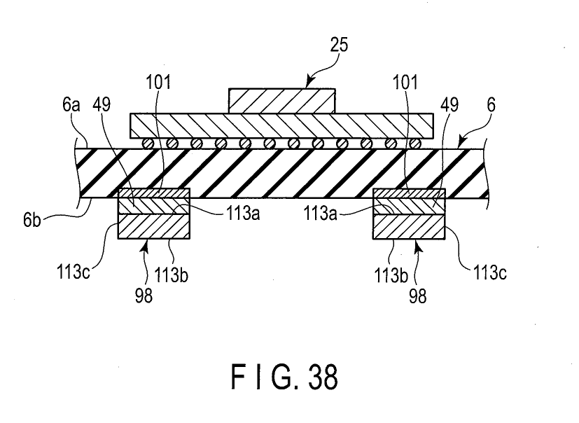

Next, an electronic apparatus 10 according to a twelfth embodiment will be described with reference to FIG. 38. In the twelfth embodiment, components having the same or similar functions as those in the second and eleventh embodiments are denoted by the same reference numerals and the description thereof will not be repeated. Structures other than the following structures are the same as those in the eleventh embodiment.

As illustrated in FIG. 38, in a reinforcing component 98 according to this embodiment, a plated layer is not provided on a third surface 113c. Plated layers are provided on a first surface 113a and a second surface 113b. For the reinforcing component 98 according to this embodiment, in a stage before a plurality of reinforcing components 98 are cut out, plating is performed on a plate-shaped material. After plating is performed, each reinforcing component 98 is punched out in an L-shape from the plate-shaped material. Therefore, no plated layer is provided on the third surface 113c and thus a fillet 114 is not formed on the third surface 113c.

According to this structure, similarly to the second embodiment, it is possible to improve the impact resistance of the electronic apparatus 10. In addition, in this embodiment, in a stage before a plurality of reinforcing components 98 are cut out, plating is performed on the plate-shaped material.

Therefore, it is possible to reduce manufacturing costs, as compared to a case in which a plating process is performed on each reinforcing component 98.

### Thirteenth Embodiment

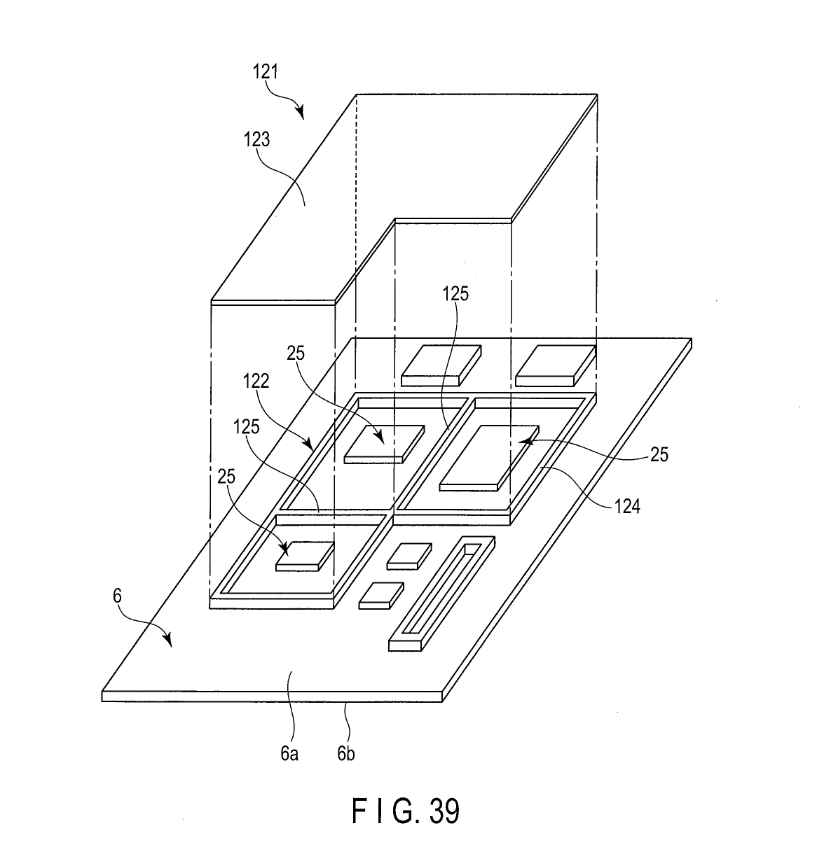

Next, an electronic apparatus 10 according to a thirteenth embodiment will be described with reference to FIG. 39. In the thirteenth embodiment, components having the same or similar functions as those in the second and ninth embodiments are denoted by the same reference numerals and the description thereof will not be repeated. Structures other than the following structures are the same as those in the second embodiment.

As illustrated in FIG. 39, a shield 121 (e.g., shield case) is provided on a first surface 6a of a circuit board 6. The shield 121 includes a frame 122 and a cover 123. An example of the frame 122 is a shield metal frame and is made of a metal material.

The frame 122 is fixed to the first surface 6a of the circuit board 6.

The frame 122 includes, for example, a frame portion 124 (e.g., outer frame) and a beam 125 which is provided inside the frame portion 124. The frame portion 124 is disposed outside a plurality of components 25 and surrounds the plurality of components 25. The beam 125 extends between the components 25.

The outward shape of the cover 123 is substantially the same as that of the frame 122. The cover 123 is attached to the frame 122 and covers the plurality of components 25 from the side opposite to the circuit board 6. The cover 123 is made of a metal material. The cover 123 and the frame 122 are members for preventing, for example, electromagnetic interference (EMI).

That is, the cover 123 and the frame 122 reduce the influence of electromagnetic waves emitted from the component 25 on other electronic components in a housing 14 and reduce the influence of electromagnetic waves emitted from other electronic components in the housing 14 or the outside on the component 25. The shield 121 improves the strength of the circuit board 6 against a static load.

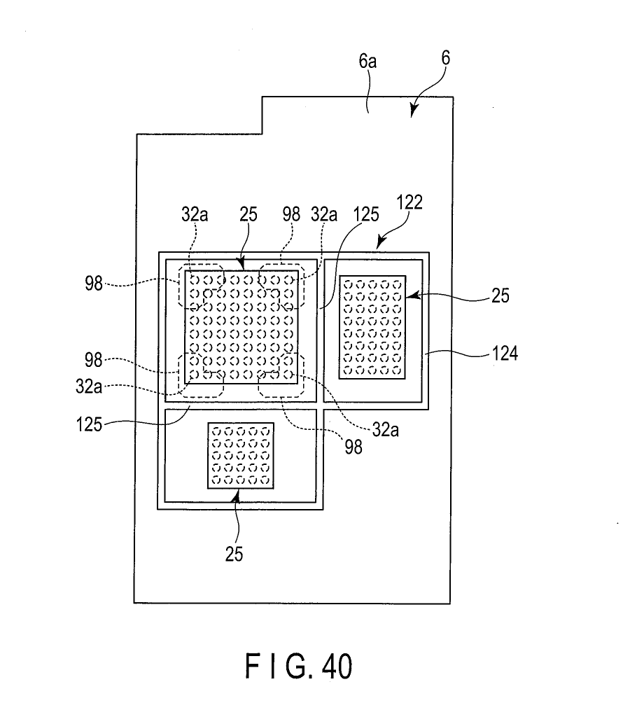

As illustrated in FIG. 40, reinforcing components 98 are provided on a second surface 6b of the circuit board 6. The reinforcing component 98 may be the electronic component 27 as in the second and third embodiment or the metal plate as in the sixth or ninth embodiment. The reinforcing components 98 are provided on the back side of an inner region of the frame 122 and reinforce the corners 33a, 33b, 33c, and 33d of the component 25. The reinforcing components 98 improve the strength of the circuit board 6 against a dynamic load (e.g., vibration or impact).

According to this structure, similarly to the second embodiment, it is possible to improve the impact resistance of the electronic apparatus 10. In addition, according to this embodiment, the shield 121 can also improve the strength of the circuit board 6 against the static load of the electronic apparatus 10.

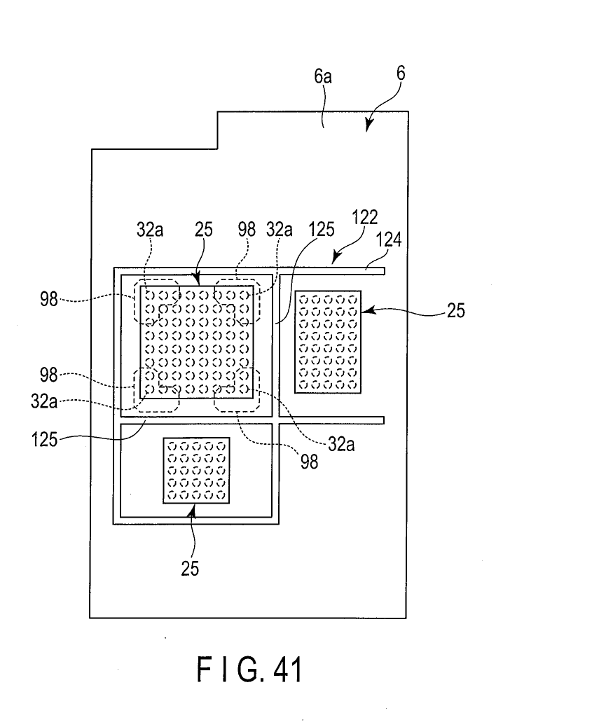

Next, first to third modifications of this embodiment will be described with reference to FIGS. 41 to 43. Structures other than the following structures are the same as those in the thirteenth embodiment.

As illustrated in FIG. 41, in the first modification, a part of the frame portion 124 of a frame 122 is cut. According to this structure, similarly to the thirteenth embodiment, it is possible to improve the impact resistance of the electronic apparatus 10 and the strength of the circuit board 6 against a static load. In this embodiment, the reinforcing components 98 on the second surface 6b reinforce the circuit board 6 and compensate for a reduction in strength due to the partial cutting of the frame 122.

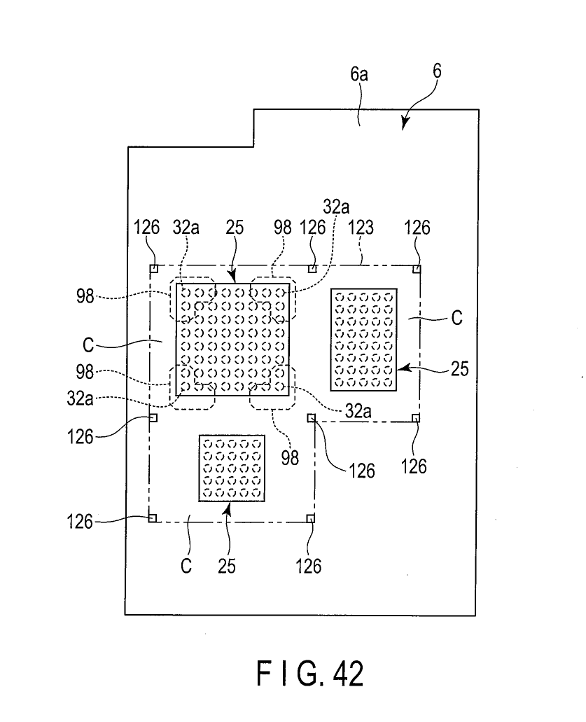

As illustrated in FIG. 42, in the second modification, instead of the frame 122, a plurality of supporting portions 126 are provided on the first surface 6a of the circuit board 6. The supporting portions 126 are provided so as to correspond to the corners of the cover 123. A gap C is formed between the supporting portions 126.

According to this structure, similarly to the thirteenth embodiment, it is possible to improve the impact resistance of the electronic apparatus 10 and the strength of the circuit board 6 against a static load. In this embodiment, the reinforcing components 98 are provided on the second surface 6b to reinforce the circuit board 6 and the supporting portions 126 are provided instead of the frame 122 to compensate for a reduction in strength.

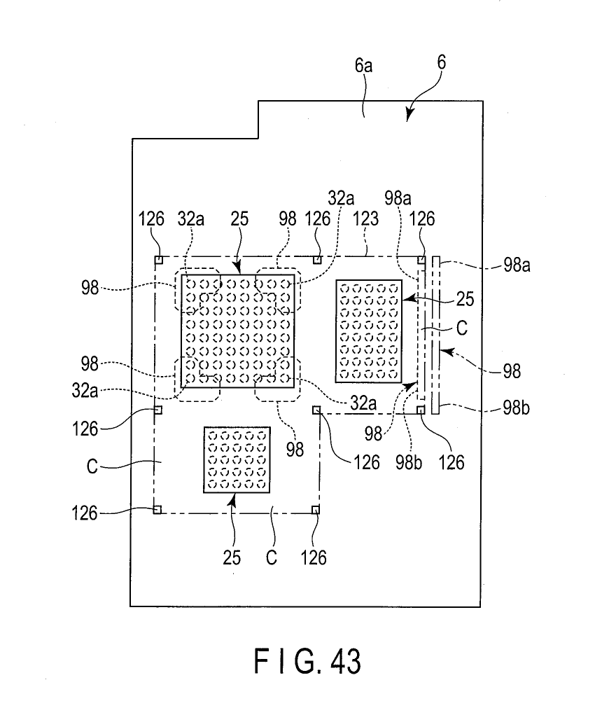

As illustrated in FIG. 43, in the third modification, similarly to the second modification, instead of the frame 122, a plurality of supporting portions 126 are provided. The reinforcing components 98 are mounted on the second surface 6b of the circuit board 6. In this modification, the reinforcing component 98 is disposed on the back side of a gap C between the supporting portions 126.

The reinforcing components 98 are mounted on the second surface 6b. The reinforcing component 98 includes a first end 98a and a second end 98b opposite to the first end 98a. The first end 98a is provided in the vicinity of one supporting portion 126. The second end 98b is provided in the vicinity of another supporting portion 126. The first end 98a and the second end 98b may be disposed on the back side of the supporting portions 126. In addition, as represented by a two-dot chain line in FIG. 43, the reinforcing component 98 may be provided outside the plurality of supporting portions 126. Instead of the above-mentioned structure, the reinforcing component 98 may be provided inside the plurality of supporting portions 126.

According to these structures, similarly to the thirteenth embodiment, it is possible to improve the impact resistance of the electronic apparatus 10 and the strength of the circuit board 6 against a static load. In this embodiment, the reinforcing components 98 on the second surface 6b reinforce the circuit board 6 and the supporting portions 126 are provided instead of the frame 122 to compensate for a reduction in strength.

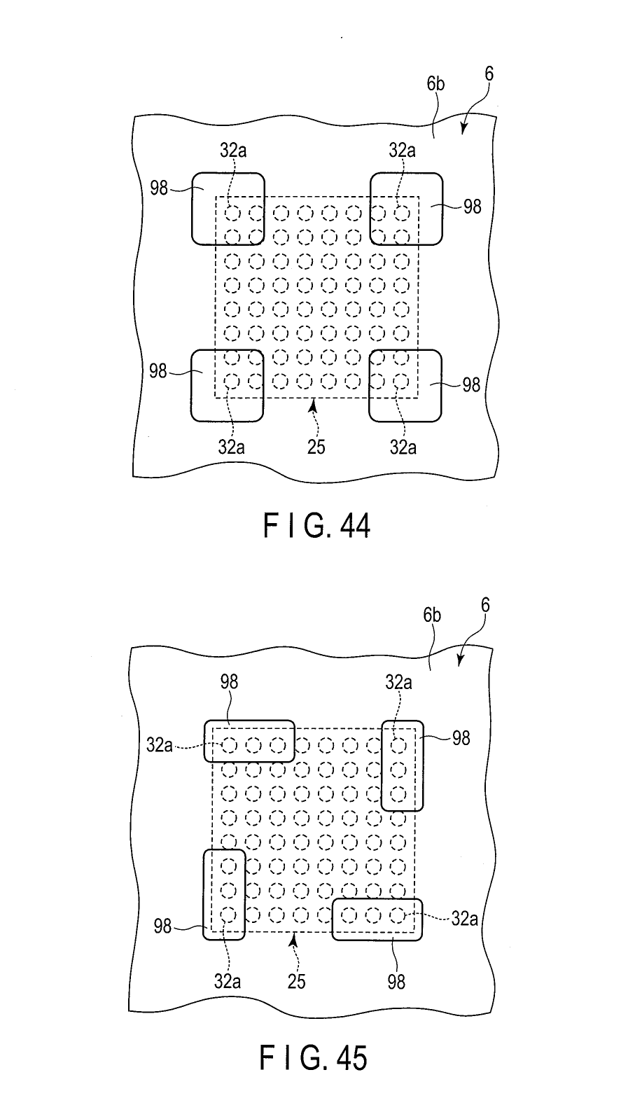

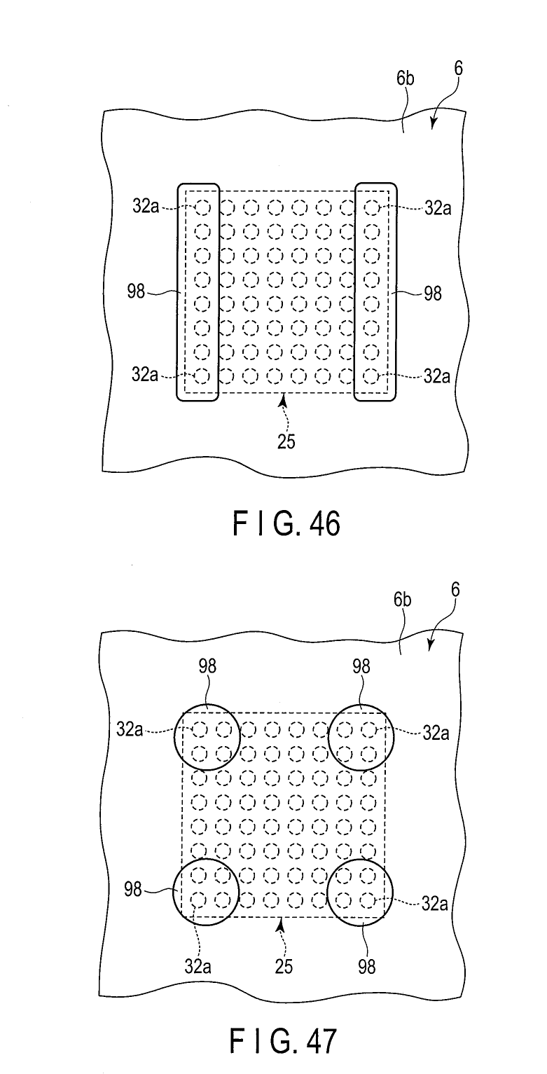

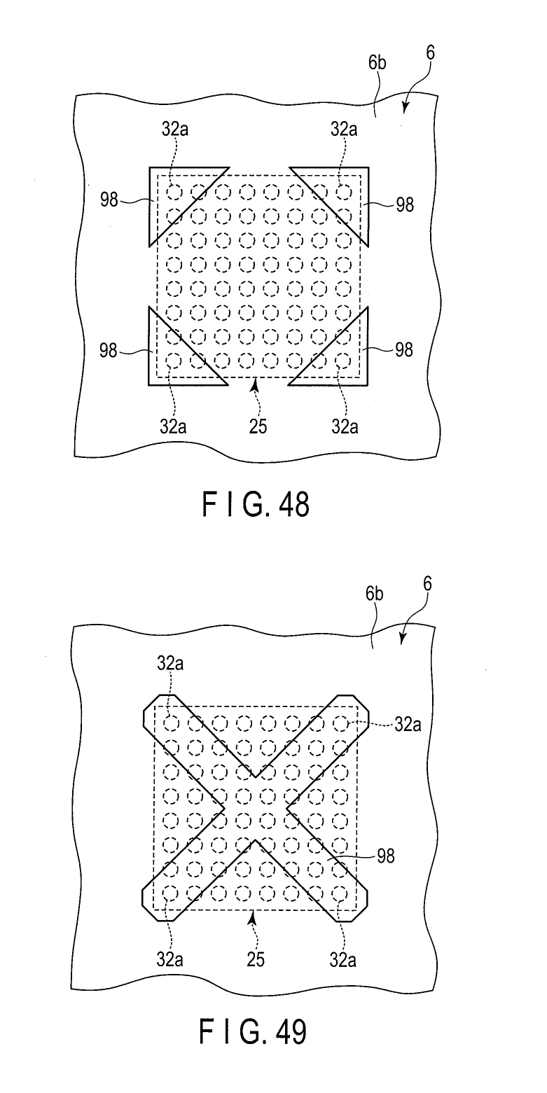

Finally, FIGS. 44 to 49 illustrate modifications of the reinforcing component 98 (i.e., second component 27) which can be applied to all of the above-described embodiments and modifications. As illustrated in FIGS. 44 to 49, the size or shape of the reinforcing component 98 is not particularly limited, but the reinforcing component 98 may have various shapes suitable for a wiring space or other purposes.

As described above, according to the first to thirteenth embodiments and the modifications thereof, it is possible to improve the impact resistance of the electronic apparatus 10.

The embodiments are not limited to the above-described embodiments, but the components according to the above-described embodiments may be changed without departing from the scope and spirit of the invention. In addition, a plurality of components according to the above-described embodiments may be appropriately combined with each other to form various structures. For example, some of the components according to the above-described embodiments may be removed. Components according to different embodiments may be appropriately combined with each other.

All components or members (i.e., all technical ideas) according to all of the above-described embodiments and modifications can be combined with each other. That is, the embodiments are not limited to substitutions or combinations which are individually described in the embodiments, but various other substitutions or combinations can be made. For example, the second component 27 according to the second to fifth embodiments may be a metal plate.

The attaching portion of the first component 25 fixed to the circuit board 6 is not limited to the bump, but various other attaching portions may be used. In the specification, the term “disposed on the back side” is not limited to a case in which a component is disposed on the back side of another component so as to completely overlap, but includes a case in which two components are disposed so as to partially overlap each other.

The second components 27 or the reinforcing components 98 do not need to be provided on the back sides of all of the corners 33a, 33b, 33c, and 33d of the component 25, but may be provided on the back side of at least one of the corners 33a, 33b, 33c, and 33d. The application of the first reinforcing portion 97 is not limited to the circuit board 6 which receives a static load from the pressing portion 92, but the first reinforcing portion 97 can be widely applied to the circuit boards 6 which receive other static loads.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A television comprising:
a housing;
a circuit board in the housing, the circuit board comprising a cutout, the cutout comprising a side, a first corner and a second corner separately at both ends of the side;
a first pad on the circuit board, the first pad comprising an L-shaped region along the first corner;
a first surface-mounted component attached to the first pad and comprising an L-shaped portion along the first corner;
a second pad on the circuit board, the second pad comprising an L-shaped region along the second corner;
a second surface-mounted component attached to the second pad and comprising an L-shaped portion along the second corner, the second surface-mounted component separate from the first surface-mounted component; and
a component comprising a body in the cutout and one or more first terminals protruding from the body and attached to the circuit board between the first surface-mounted component and the second surface-mounted component.

2. The television of claim 1,
wherein a gap between the first surface-mounted component and the second surface-mounted component is larger than the first surface-mounted component.

3. The television of claim 1,
wherein the first terminals are along the side of the cutout between the first surface-mounted component and the second surface-mounted component.

4. The television of claim 1,
wherein the housing comprises an opening facing the body, and
the body is configured to receive an external component.

5. The television of claim 1,
wherein the circuit board comprises a first region along the side of the cutout and a second region, the first corner is between the first region and the second region, and
the body comprises a second terminal attached to the second region.

6. The television of claim 5,
wherein at least a portion of the second terminal is between the first surface-mounted component and the cutout.

7. The television of claim 1,
wherein at least one of the first surface-mounted component and the second surface-mounted component comprises an L-shaped metal plate.

8. The television of claim 1, further comprising:
an adhesive on the circuit board,
wherein the circuit board comprises a first surface, a second surface opposite the first surface, and a third surface between the first surface and the second surface, and
at least a portion of the adhesive is on the third surface at the first corner.

9. An electronic apparatus comprising:
a housing;
a circuit board in the housing, the circuit board comprising a cutout comprising a corner;
a pad comprising L-shaped region along the corner on the circuit board; and
a surface-mounted component attached to the pad and comprising an L-shaped portion along the corner.

10. An electronic apparatus comprising:
a housing;
a circuit board in the housing, the circuit board comprising a cutout; and
a surface-mounted component along an edge of the cutout on the circuit board.
